(19) United States
(12) Patent Application Publication
(10) Pub. No.: US 2026/0101666 A1
(43) Pub. Date: Apr. 9, 2026

(54) DEPOSITION MASK, METHOD OF MANUFACTURING THE DEPOSITION MASK, AND ELECTRONIC DEVICE MANUFACTURED BY USING THE DEPOSITION MASK

(71) Applicant: Samsung Display Co., LTD., Yongin-si (KR)

(72) Inventors: Young Jin SONG, Yongin-si (KR); Jeong Kuk KIM, Yongin-si (KR); Seung Sok SON, Yongin-si (KR)

(21) Appl. No.: 19/249,117

(22) Filed: Jun. 25, 2025

(30) Foreign Application Priority Data
Oct. 8, 2024 (KR) 10-2024-0136444

(51) Int. Cl. H10K 71/16; C23C 16/04; H10K 59/12; H10K 59/122

(52) U.S. Cl. CPC H10K 71/166; C23C 16/042; H10K 59/1201; H10K 59/122

(57) ABSTRACT

A deposition mask includes a mask frame having a cell opening, an intermediate inorganic film disposed on the mask frame, and a membrane disposed on the intermediate inorganic film and having a plurality of pixel openings communicating with the cell opening. The intermediate inorganic film is formed of a material including germanium.

This application claims priority to Korean Patent Application No. 10-2024-0136444, filed on Oct. 8, 2024, and all the benefits accruing therefrom under 35 U.S.C. § 119, the content of which in its entirety is herein incorporated by reference.

### BACKGROUND

### 1. Field

The present disclosure relates to a deposition mask, a method of manufacturing the deposition mask, and an electronic device manufactured by using the deposition mask.

### 2. Description of the Related Art

Wearable devices in which a focus is formed at a distance close to user's eyes have been developed in the form of glasses or a helmet. For example, the wearable device may be a head mounted display (HMD) device or AR glasses. The wearable device may provide an augmented reality (hereinafter, referred to as “AR”) screen or a virtual reality (hereinafter, referred to as “VR”) screen to a user.

In the case of wearable devices such as, for example, the HMD device or the AR glasses, a display specification of approximately 3000 PPI (pixels per inch) or higher is implemented to allow users to use them for a long time without symptoms of dizziness. To this end, organic light emitting diode on silicon (OLEDoS) technology that is used in a high-resolution small organic light emitting display device is emerging. The OLEDoS is a technology in which organic light emitting diodes (OLED) are disposed on a semiconductor substrate on which complementary metal oxide semiconductor (CMOS) elements are disposed.

In some cases, in order to manufacture a display panel with a high resolution of about 3000 PPI or higher, a high-resolution deposition mask is implemented. For example, the deposition mask may be manufactured by forming a membrane having a plurality of pixel openings on a substrate such as, for example, a silicon wafer, and partially etching the substrate to form cell openings that expose the pixel openings. For example, a silicon nitride film may be used as the membrane, and the cell openings may be formed by a wet etching process using a tetramethyl ammonium hydroxide (TMAH) solution. However, when using the TMAH solution, the etching rate would be very low, and the membrane might be damaged by hydrogen (H₂) bubbles generated by a reaction between the silicon substrate and the TMAH solution.

### SUMMARY

Aspects and features of embodiments of the present disclosure provide a deposition mask capable of shortening a manufacturing time and preventing damage to a membrane, a method of manufacturing the same, and an electronic device manufactured by using the same.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to an aspect of the present disclosure, a deposition mask may include a mask frame having a cell opening, an intermediate inorganic film disposed on the mask frame, and a membrane disposed on the intermediate inorganic film and having a plurality of pixel openings communicating with the cell opening. The intermediate inorganic film may be formed of a material including germanium.

According to some embodiments of the present disclosure, the intermediate inorganic film may be formed of at least one selected from the group consisting of amorphous germanium, single crystal germanium, polycrystalline germanium, and silicon germanium.

According to some embodiments of the present disclosure, the mask frame may be formed of single crystal silicon, and the intermediate inorganic film may be formed of boron-doped germanium or boron-doped silicon germanium.

According to some embodiments of the present disclosure, the intermediate inorganic film may have a thickness ranging from 50 nm to 1 μm.

According to some embodiments of the present disclosure, the membrane may be formed of silicon nitride and have a thickness ranging from about 0.5 μm to about 3 μm.

According to some embodiments of the present disclosure, the deposition mask may further include a buffer inorganic film disposed between the mask frame and the intermediate inorganic film.

According to some embodiments of the present disclosure, the buffer inorganic film may be formed of silicon oxide and have a thickness ranging from about 0.5μm to about 2 μm.

According to another aspect of the present disclosure, a method of manufacturing a deposition mask may include forming an intermediate inorganic film on a mask substrate, forming, on the intermediate inorganic film, a membrane having a plurality of pixel openings, patterning the mask substrate, wherein patterning the mask substrate forms a cell opening partially exposing the intermediate inorganic film, and removing a portion of the intermediate inorganic film exposed by the cell opening such that the cell opening communicates with the pixel openings. The intermediate inorganic film may be formed of a material including germanium.

According to some embodiments of the present disclosure, the intermediate inorganic film may be formed of at least one selected from the group consisting of amorphous germanium, single crystal germanium, polycrystalline germanium, and silicon germanium.

According to some embodiments of the present disclosure, the mask substrate may be formed of single crystal silicon, and the intermediate inorganic film may be formed of boron-doped germanium or boron-doped silicon germanium.

According to some embodiments of the present disclosure, the intermediate inorganic film may be formed to have a thickness ranging from about 50 nm to about 1 μm.

According to some embodiments of the present disclosure, the membrane may be formed of silicon nitride and be formed to have a thickness ranging from about 0.5 μm to about 3 μm.

According to some embodiments of the present disclosure, patterning the mask substrate may include forming the cell opening by performing a wet etching process using an etchant including potassium hydroxide (KOH).

According to some embodiments of the present disclosure, the wet etching process may be performed at a temperature ranging from about 40° C. to about 100° C.

According to some embodiments of the present disclosure, removing the portion of the intermediate inorganic film exposed by the cell opening may include performing by a wet etching process using an etchant including hydrofluoric acid (HF), hydrogen peroxide (H2O2), acetic acid (CH3COOH), and water (H2O).

According to some embodiments of the present disclosure, removing the portion of the intermediate inorganic film exposed by the cell opening may include performing a wet etching process using an etchant including ammonium hydroxide (NH4OH), hydrogen peroxide (H2O2), and water (H2O).

According to some embodiments of the present disclosure, the method may further include forming a buffer inorganic film on the mask substrate. The intermediate inorganic film may be formed on the buffer inorganic film.

According to some embodiments of the present disclosure, the buffer inorganic film may be formed of silicon oxide and be formed to have a thickness ranging from about 0.5 μm to about 2 μm.

According to some embodiments of the present disclosure, the method may further include partially removing the buffer inorganic film such that the intermediate inorganic film is partially exposed by the cell opening.

According to some embodiments of the present disclosure, the method may further include forming, on a rear surface of the mask substrate, a rear inorganic film exposing a rear portion of the mask substrate. Patterning the mask substrate may include forming the cell opening by performing a wet etching process using the rear inorganic film as an etching mask.

According to still another aspect of the present disclosure, an electronic device may include a display panel. The display panel may include a substrate and light emitting layers formed on the substrate using a deposition mask. The deposition mask may include a mask frame having a cell opening, an intermediate inorganic film disposed on the mask frame, and a membrane disposed on the intermediate inorganic film and having a plurality of pixel openings communicating with the cell opening. The intermediate inorganic film may be formed of a material including germanium.

According to the embodiments of the present disclosure, the intermediate inorganic film may function as an etch stop film in a wet etching process for forming the cell openings. In particular, the etchant including potassium hydroxide (KOH) may be prevented by the intermediate inorganic film from being provided to the mask substrate through the pixel openings, such that damage to the membrane can be prevented during the wet etching process. In some aspects, when the etchant containing potassium hydroxide (KOH) is used, the amount of time associated with forming the cell openings may be greatly reduced.

Other features and embodiments may be apparent from the following detailed description and the drawings.

### BRIEF DESCRIPTION OF THE DRAWINGS

The above and other aspects and features of the present disclosure will become more apparent by describing in detail example embodiments thereof with reference to the attached drawings, in which:

FIG. 1 is a block diagram of an electronic device according to an embodiment of the present disclosure;

FIG. 2 is a schematic diagram of an electronic device according to various embodiments of the present disclosure;

FIG. 3 is an exploded perspective view illustrating a display device according to an embodiment of the present disclosure;

FIG. 4 is a block diagram illustrating the display device illustrated in FIG. 3;

FIG. 5 is an equivalent circuit diagram illustrating an example of a first sub-pixel illustrated in FIG. 4;

FIG. 6 is a schematic plan view illustrating an example of a display panel illustrated in FIG. 3;

FIG. 7 is a schematic enlarged plan view illustrating an example of a display area illustrated in FIG. 6;

FIG. 8 is a schematic enlarged plan view illustrating another example of the display area illustrated in FIG. 6;

FIG. 9 is a schematic cross-sectional view illustrating an example of the display panel taken along line I1-I1′ illustrated in FIG. 7;

FIG. 10 is a schematic cross-sectional view illustrating another example of the display panel taken along line I1-I1′ illustrated in FIG. 7;

FIG. 11 is a schematic perspective view illustrating an example of a head mounted display;

FIG. 12 is a schematic exploded perspective view illustrating the head mounted display illustrated in FIG. 11;

FIG. 13 is a schematic perspective view illustrating another example of the head mounted display;

FIG. 14 is a schematic diagram illustrating a deposition mask and a deposition apparatus including the deposition mask according to an embodiment of the present disclosure;

FIG. 15 is a schematic bottom view illustrating the backplane substrate illustrated in FIG. 14;

FIG. 16 is a schematic plan view illustrating the deposition mask illustrated in FIG. 14;

FIG. 17 is a schematic enlarged plan view illustrating the mask cell regions illustrated in FIG. 16;

FIG. 18 is a schematic cross-sectional view taken along line I2-I2′ illustrated in FIG. 17;

FIG. 19 is a cross-sectional view illustrating a deposition mask according to another embodiment of the present disclosure;

FIGS. 20 to 25 are schematic cross-sectional views illustrating a method of manufacturing a deposition mask according to still another embodiment of the present disclosure; and

FIGS. 26 to 33 are schematic cross-sectional views illustrating a method of manufacturing a deposition mask according to still another embodiment of the present disclosure.

### DETAILED DESCRIPTION

The invention will now be described more fully hereinafter with reference to the accompanying drawings, in which various embodiments of the present disclosure are illustrated. Aspects supported by the present disclosure may, however, be embodied in different forms and should not be construed as limited to the embodiments set forth herein. Rather, the example embodiments are provided such that this disclosure will be thorough and complete, and will fully convey the scope of example aspects of the present disclosure to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” and the like may be used herein to describe various elements, these elements should not be limited by these terms. These terms are used to distinguish one element from another element. For instance, a first element discussed below could be termed a second element without departing from the teachings of the invention. similarly, the second element could also be termed the first element.

The terminology used herein is for the purpose of describing particular embodiments and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as, for example, “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of each of various embodiments of the disclosure may be partially or entirely combined with each other and may technically variously interwork with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel”means approximately or actually parallel.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

The display device according to an embodiment of the present disclosure can be applied to various electronic devices. The electronic device according to embodiments of the present disclosure includes the display device described herein, and may further include modules or devices having additional functions in addition to the display device.

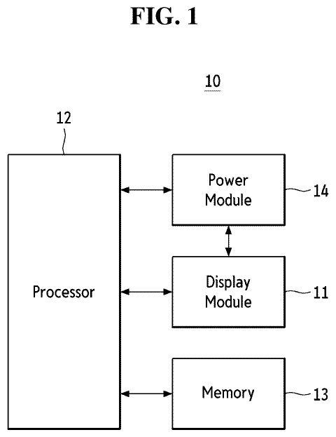

FIG. 1 is a block diagram of an electronic device according to an embodiment of the present disclosure.

Referring to FIG. 1, the electronic device 10 according to an embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information supportive of the operation of the processor 12 or the display module 11. In an example in which the processor 12 executes an application stored in the memory 13, an image data signal and/or an input control signal is transmitted to the display module 11, and the display module 11 can process the received signal and output image information through a display screen.

The power module 14 may include a power supply module such as, for example, a power adapter or a battery, and a power conversion module that converts the power supplied by the power supply module to generate power for the operation of the electronic device 10.

At least one of the components of the electronic device 10 according to embodiments of the present disclosure may be included in the display device 20 according to the embodiments of the present disclosure. In some aspects, some modules of the individual modules functionally included in one module may be included in the display device 20, and other modules may be provided separately from the display device 10. For example, the display device 20 may include the display module 11, and the processor 12, the memory 13, and the power module 14 may be provided in the form of other devices within the electronic device 10 other than the display device 20.

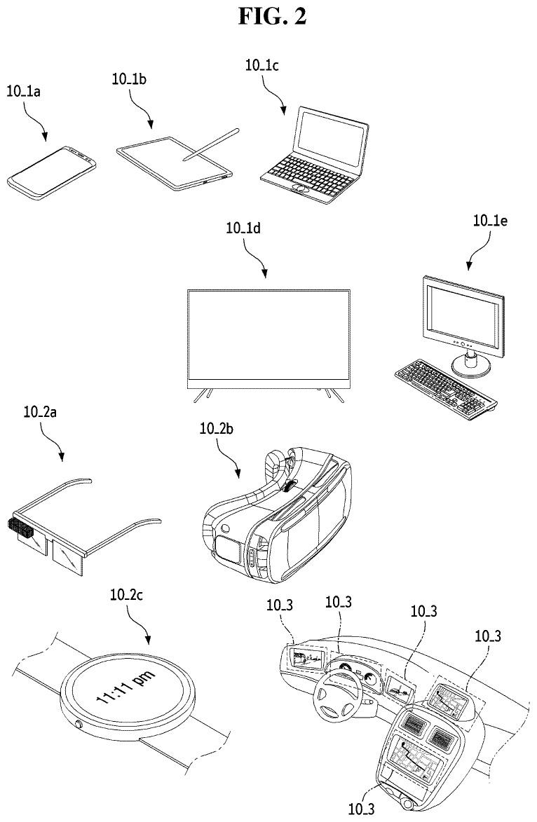

FIG. 2 is a schematic diagram of an electronic device according to various embodiments of the present disclosure.

Referring to FIG. 2, various electronic devices to which display devices 20 according to embodiments of the present disclosure are applied may include not only image display electronic devices such as, for example, a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as, for example, a CID (Center Information Display) and a room mirror display arranged on a dashboard, center fascia, and dashboard of an automobile.

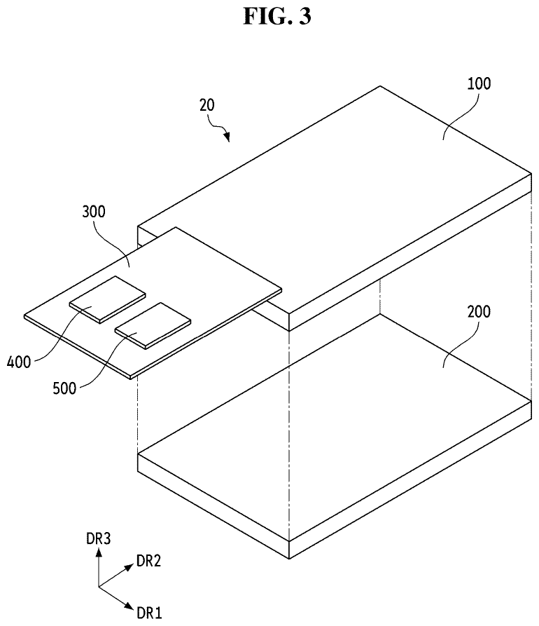

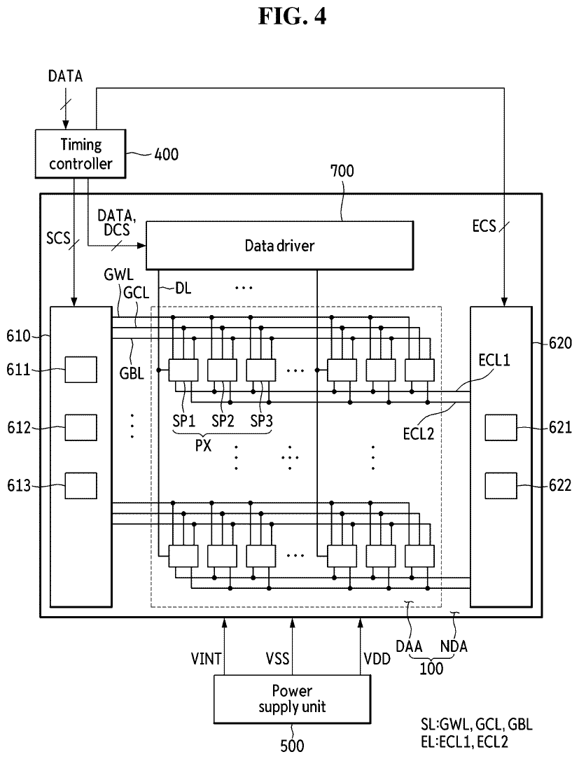

FIG. 3 is an exploded perspective view illustrating a display device according to an embodiment of the present disclosure. FIG. 4 is a block diagram illustrating the display device illustrated in FIG. 3.

Referring to FIGS. 3 and 4, a display device 20 according to an embodiment may be a device displaying a moving image or a still image. A display device 20 according to an embodiment may be used as the electronic device 10 or the display module 11 of the electronic device 10. For example, the display device 20 according to an embodiment may be applied to portable electronic devices 10 such as, for example, a mobile phone, a smartphone, a tablet personal computer, a mobile communication terminal, an electronic organizer, an electronic book, a portable multimedia player (PMP), a navigation system, an ultra mobile PC (UMPC), and the like. The display device 20 according to an embodiment may be applied as a display module 11 of electronic devices 10 such as, for example, a television, a laptop, a monitor, a billboard, or an Internet-of-Things (IoT) terminal, and the like. The display device 20 according to an embodiment may be applied to electronic devices 10 such as, for example, a smart watch, a watch phone, a head mounted display (HMD) for implementing virtual reality and augmented reality, and the like.

The display device 20 according to an embodiment may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 20 may conform to the planar shape of the display panel 100, but embodiments of the present disclosure are not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as illustrated in FIG. 4.

The plurality of pixels PX may be disposed in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

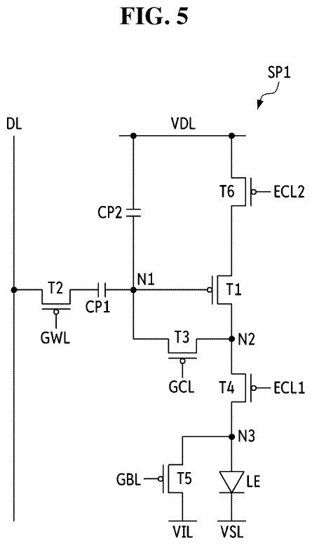

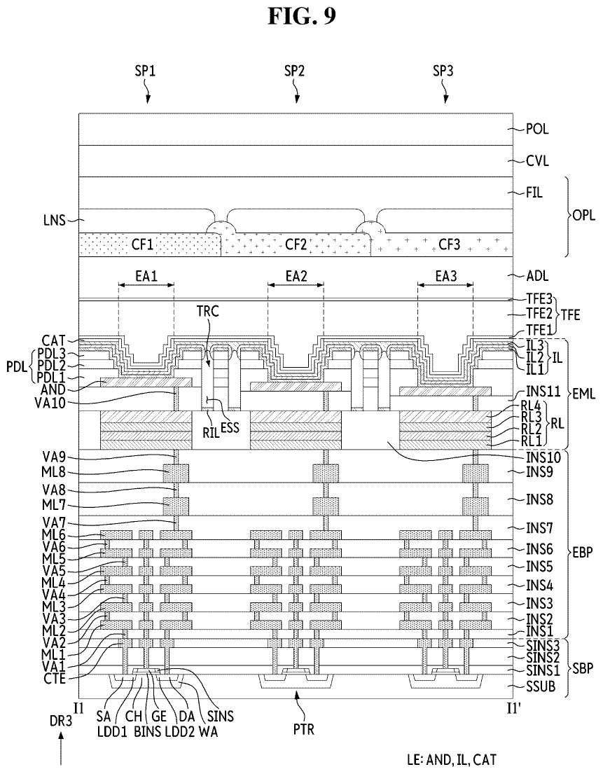

The plurality of pixels PX may include a plurality of sub-pixels SP1, SP2, and SP3. The plurality of sub-pixels SP1, SP2, and SP3 may include a plurality of pixel transistors as illustrated in FIG. 5, and the plurality of pixel transistors may be formed by a semiconductor process and disposed on a semiconductor substrate SSUB (see FIG. 9). For example, the plurality of pixel transistors of the data driver 700 may be formed of complementary metal oxide semiconductor (CMOS), but embodiments of the present disclosure are not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be disposed in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 9) through a semiconductor process. For example, the plurality of scan transistors and the plurality of light emitting transistors may be formed of CMOS, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

The data driver 700 may include a plurality of data transistors, and the plurality of data transistors may be formed on the semiconductor substrate SSUB (see FIG. 9) through a semiconductor process. For example, the plurality of data transistors may be formed of CMOS, but embodiments of the present disclosure are not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer having high thermal conductivity, such as, for example, graphite, silver (Ag), copper (Cu), or aluminum (Al).

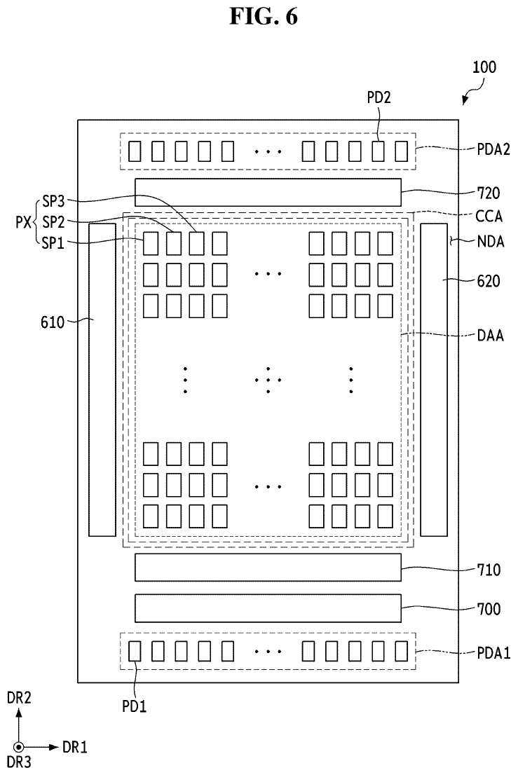

The circuit board 300 may be electrically connected to a plurality of first pads PD1 (see FIG. 6) of a first pad portion PDA1 (see FIG. 6) of the display panel 100 by using a conductive adhesive member such as, for example, an anisotropic conductive film. The circuit board 300 may be a flexible printed circuit board with a flexible material, or a flexible film. Although the circuit board 300 is illustrated in FIG. 3 as being unfolded, the circuit board 300 may be bent. In this case, one end of the circuit board 300 may be disposed on the rear surface of the display panel 100 and/or the rear surface of the heat dissipation layer 200. The other end of the circuit board 300 may be connected to the plurality of first pads PD1 (see FIG. 6) of the first pad portion PDA1 (see FIG. 6) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 5.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 9) through a semiconductor process. For example, the plurality of timing transistors and the plurality of power transistors may be formed of CMOS, but embodiments of the present disclosure are not limited thereto. Each of the timing control circuit 400 and the power supply circuit 500 may be disposed between the data driver 700 and the first pad portion PDA1 (see FIG. 6).

FIG. 5 is an equivalent circuit diagram illustrating an example of a first sub-pixel illustrated in FIG. 4.

Referring to FIG. 5, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 may include a plurality of transistors T1 to T6, a light emitting element LE, a first capacitor CP1, and a second capacitor CP2.

The light emitting element LE emits light in response to a driving current flowing through the channel of the first transistor T1. The emission amount of the light emitting element LE may be proportional to the driving current. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but embodiments of the present disclosure are not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current (hereinafter referred to as “driving current”) flowing between the source electrode and the drain electrode thereof according to a voltage applied to the gate electrode thereof.

A second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be disposed between the first node N1 and the second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light emitting element LE. A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

The sixth transistor T6 may be disposed between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a P-type MOSFET, but embodiments of the present disclosure are not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 5 that the first sub-pixel SP1 includes six transistors T1 to T6 and two capacitors C1 and C2, it should be noted that the equivalent circuit diagram of the first sub-pixel SP1 is not limited to that illustrated in FIG. 5. For example, the number of transistors and the number of capacitors of the first sub-pixel SP1 are not limited to those illustrated in FIG. 5.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 5. Therefore, the description of the equivalent circuit diagram of the second sub-pixel SP2 and the equivalent circuit diagram of the third sub-pixel SP3 is not repeated in the present disclosure.

FIG. 6 is a schematic plan view illustrating an example of a display panel illustrated in FIG. 3.

Referring to FIG. 6, the display area DAA of the display panel 100 according to an embodiment includes the plurality of pixels PX arranged in a matrix form. The non-display area NDA of the display panel 100 according to an embodiment includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. However, embodiments of the present disclosure are not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2. The first pad portion PDA1 may be disposed outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board formed of a rigid material or a flexible printed circuit board formed of a flexible material.

The second pad portion PDA2 may be disposed on the fourth side of the display area DAA. For example, the second pad portion PDA2 may be disposed on the other side of the display area DAA in the second direction DR2. The second pad portion PDA2 may be disposed outside the second distribution circuit 720 in the second direction DR2.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2.

A cathode connection part CCA may be a region where a second electrode CAT (see FIG. 9) of a display element layer EML (see FIG. 9) is connected to the first driving voltage line VSL of the non-display area NDA. The cathode connection part CCA may be disposed outside at least one side of the display area DAA. For example, the cathode connection part CCA may be disposed outside at least on one side among the left side, the right side, the upper side, and the lower side of the display area DAA. Alternatively, the cathode connection part CCA may be disposed to surround the display area DAA as illustrated in FIG. 6 in order to minimize a deviation in the first driving voltage VSS caused by voltage drop (IR drop) or voltage rise (IR rising) of the second electrode CAT in the display area DAA.

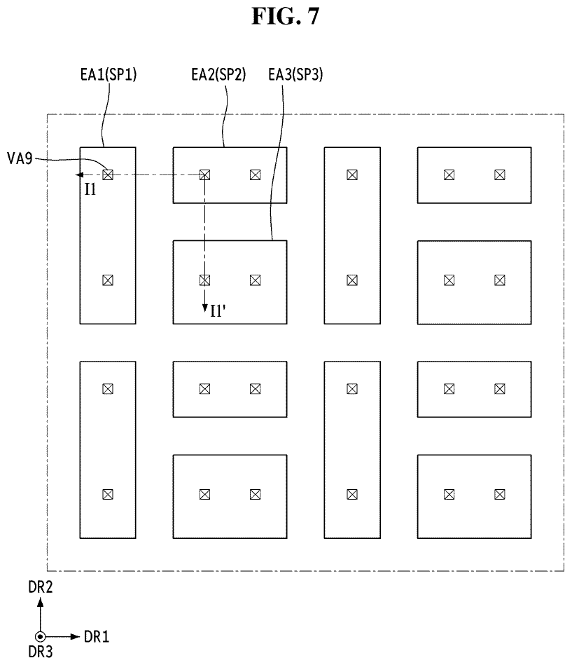

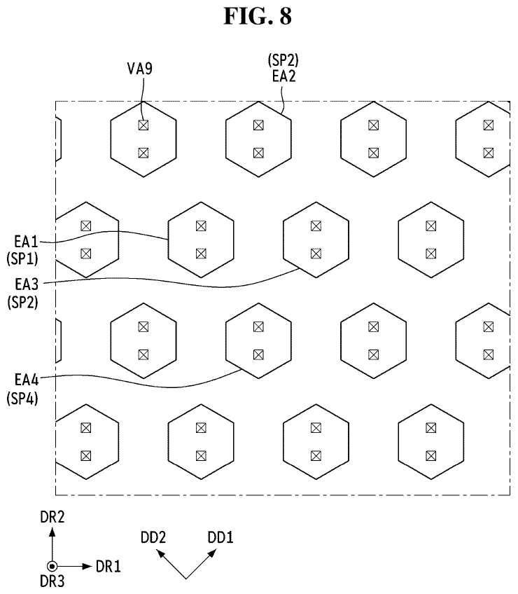

FIG. 7 is a schematic enlarged plan view illustrating an example of a display area illustrated in FIG. 6. FIG. 8 is a schematic enlarged plan view illustrating another example of the display area illustrated in FIG. 6.

Referring to FIGS. 7 and 8, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in plan view, a quadrilateral or hexagonal shape as illustrated in FIGS. 7 and 8, but embodiments of the present disclosure are not limited thereto. The first emission area EA1, the second emission area EA2, and the third emission area EA3 may have a polygonal shape other than a quadrangle or hexagon, a circular shape, an elliptical shape, or an atypical shape in plan view.

As illustrated in FIG. 7, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In some aspects, the second emission area EA2 and the third emission area EA3 may be adjacent to each other in the second direction DR2. The area of the first emission area EA1, the area of the second emission area EA2, and the area of the third emission area EA3 may be different.

Alternatively, as illustrated in FIG. 8, the emission areas EA1, EA2, EA3, and EA4 may have a hexagonal shape in plan view. In this case, the first emission area EA1 and the third emission area EA3 may be adjacent in the first direction DR1, and the second emission area EA2 and the fourth emission area EA4 may be adjacent in the second direction DR2. In some aspects, the first emission area EA1 and the second emission area EA2 may be adjacent in a first diagonal direction DD1, and the second emission area EA2 and the third emission area EA3 may be adjacent in a second diagonal direction DD2. In some aspects, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to 460 nm, the green wavelength band may be a wavelength band of light whose main peak wavelength is in the range of approximately 480 nm to 560 nm, and the red wavelength band may be a wavelength band of light whose main peak wavelength is in the range of approximately 600 nm to 750 nm.

As illustrated in FIG. 7, each of the plurality of pixels PX may include three emission areas EA1, EA2, and EA3, or may include four emission areas EA1, EA2, EA3, and EA4 as illustrated in FIG. 8. In this case, the fourth emission area EA4 may emit the same second light as the second emission area EA2, but embodiments of the present disclosure are not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombic shape as illustrated in FIG. 8, or a hexagonal structure in which the emission areas are arranged in a hexagonal shape.

FIG. 9 is a schematic cross-sectional view illustrating an example of the display panel taken along line I1-I1′ illustrated in FIG. 7.

Referring to FIG. 9, the display panel 100 includes a semiconductor backplane SBP, a light emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 5.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the first type impurity. In an example in which the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

A first semiconductor insulating film SINS1 may be disposed on the semiconductor substrate SSUB. A second semiconductor insulating film SINS2 may be disposed on the first semiconductor insulating film SINS1.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be formed of silicon carbonitride (SiCN) or a silicon oxide (SiOx)-based inorganic film, but embodiments of the present disclosure are not limited thereto.

The semiconductor substrate SSUB may be replaced with a glass substrate or a polymer resin substrate such as, for example, polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP includes a plurality of conductive layers ML1 to ML8, a plurality of vias VA1 to VA9, and a plurality of interlayer insulating films INS1 to INS9.

The first to ninth interlayer insulating films INS1 to INS9 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 illustrated in FIG. 5.

For example, the first to sixth transistors T1 to T6 are formed in the semiconductor backplane SBP, and the connection of the first to sixth transistors T1 to T6 and the first and second capacitors C1 and C2 is accomplished through the first to eighth conductive layers ML1 to ML8. In some aspects, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be formed of substantially the same material. First to eighth interlayer insulating films INS1 to INS8 may be formed of a silicon oxide (SiOx)-based inorganic layer, but embodiments of the present disclosure are not limited thereto.

A ninth interlayer insulating film INS9 may be disposed on the eighth interlayer insulating film INS8 and the eighth conductive layer ML8. The ninth interlayer insulating film INS9 may be formed of a silicon oxide (SiOx)-based inorganic film, but embodiments of the present disclosure are not limited thereto.

Each of the ninth vias VA9 may penetrate the ninth interlayer insulating film INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

The display element layer EML may be disposed on the light emitting element backplane EBP. The display element layer EML may include the tenth and eleventh interlayer insulating films INS10 and INS11, reflective electrodes RL, the first electrodes AND, a light emitting stack IL, the second electrode CAT, a pixel defining film PDL, and a plurality of trenches TRC.

The reflective electrodes RL may be disposed on the ninth interlayer insulating film INS9. Each of the reflective electrodes RL may include at least one reflective electrode RL1, RL2, RL3, and RL4. For example, each of the reflective electrodes RL may include the first to fourth reflective electrodes RL1, RL2, RL3, and RL4 as illustrated in FIG. 9.

The first reflective electrodes RL1 may be disposed on the ninth interlayer insulating film INS9, and may be connected to the ninth via VA9. Each of the second reflective electrodes RL2 may be disposed on the first reflective electrode RL1 corresponding thereto. Each of the third reflective electrodes RL3 may be disposed on the second reflective electrode RL2 corresponding thereto. Each of the fourth reflective electrodes RL4 may be disposed on the third reflective electrode RL3 corresponding thereto.

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may contain titanium nitride (TiN), the second reflective electrodes RL2 may contain aluminum (Al), the third reflective electrodes RL3 may contain titanium nitride (TiN), and the fourth reflective electrodes RL4 may include titanium (Ti).

The tenth interlayer insulating film INS10 may be disposed on the ninth interlayer insulating film INS9. The tenth interlayer insulating film INS10 may be disposed between the reflective electrodes RL adjacent to each other. The tenth interlayer insulating film INS10 may be a film for flattening a stepped portion caused by the reflective electrodes RL. The eleventh interlayer insulating film INS11 may be disposed on the tenth interlayer insulating film INS10 and the reflective electrodes RL.

The tenth interlayer insulating film INS10 and the eleventh interlayer insulating film INS11 may be formed of a silicon oxide (SiOx)-based inorganic film, but embodiments of the present disclosure are not limited thereto.

The eleventh interlayer insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

For example, as illustrated in FIG. 9, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In this case, the distance between the first electrode AND and the reflective electrode RL in the first sub-pixel SP1 is greater than the distance between the first electrode AND and the reflective electrode RL in the second sub-pixel SP2. In some aspects, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh interlayer insulating film INS11 and be connected to the exposed fourth reflective electrode RL4. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be disposed on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is disposed.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOx)-based inorganic film. Alternatively, the first pixel defining film PDL1 and the third pixel defining film PDL3 may be formed of a silicon nitride (SiNx)-based inorganic film, whereas the second pixel defining film PDL2 may be formed of a silicon oxide (SiOx)-based inorganic film. The first pixel defining film PDL1, the second pixel defining film PDL2, and the third pixel defining film PDL3 may each have a thickness of about 500 Å.

In order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. The eleventh interlayer insulating film INS11 may be partially recessed at each of the plurality of trenches TRC.

At least one trench TRC may be disposed between the neighboring sub-pixels SP1, SP2, and SP3. Although FIG. 9 illustrates that two trenches TRC are disposed between the neighboring sub-pixels SP1, SP2, and SP3, embodiments of the present disclosure are not limited thereto.

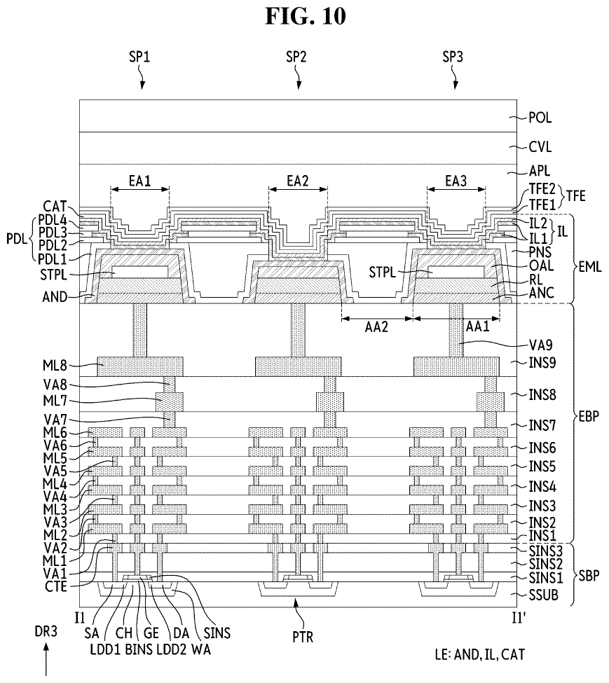

The light emitting stack IL may include a plurality of stack layers IL1, IL2, and IL3. FIG. 9 illustrates that the light emitting stack IL has a three-tandem structure including a first stack layer IL1, a second stack layer IL2, and a third stack layer IL3, but embodiments of the present disclosure are not limited thereto. For example, the light emitting stack IL may have a two-tandem structure including two stack layers as illustrated in FIG. 10.

In the three-tandem structure, the light emitting stack IL may have a tandem structure including a plurality of intermediate layers IL1, IL2, and IL3 that emit different lights. For example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and a residual film RIL disposed on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the residual film IL and the second stack layer IL2 in the trench TRC. The third stack layer IL3 may be disposed on the second stack layer IL2. The third stack layer IL3 is not cut off by the trench TRC and may be disposed such that the third stack layer IL3 covers the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In some aspects, in the two-tandem structure, each of the plurality of trenches TRC may be a structure for cutting off the charge generation layer and the lower stack layer disposed between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, a different structure may be present instead of the trench TRC. For example, instead of the trench TRC, a reverse tapered partition wall may be disposed on the pixel defining film PDL.

In some aspects, FIG. 9 illustrates that the light emitting stack IL that emits light is disposed in the first emission area EA1, the second emission area EA2, and the third emission area EA3, but embodiments of the present disclosure are not limited thereto. For example, instead of the light emitting stack IL, the first light emitting layer may be disposed in the first emission area EA1, and may be omitted from the second emission area EA2 and the third emission area EA3. Furthermore, the second light emitting layer may be disposed in the second emission area EA2 and may be omitted from the first emission area EA1 and the third emission area EA3. Furthermore, the third light emitting layer may be disposed in the third emission area EA3 and may be omitted from the first emission area EA1 and the second emission area EA2. In this case, first to third color filters CF1, CF2, and CF3 of the optical layer OPL may be omitted.

The second electrode CAT may be disposed on the light emitting stack IL. That is, the second electrode CAT may be disposed on the third stack layer IL3. The second electrode CAT may be formed of a transparent conductive material (TCO) such as, for example, ITO or IZO that can transmit light or a semi-transmissive conductive material such as, for example, magnesium (Mg), silver (Ag), or an alloy of Mg and Ag. In an example in which the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE3 to prevent oxygen or moisture from permeating into the display element layer EML. The first encapsulation inorganic film TFE1 may be disposed on the second electrode CAT, and the second encapsulation inorganic film TFE3 may be disposed above the first encapsulation inorganic film TFE1. The first encapsulation inorganic film TFE1 and the second encapsulation inorganic film TFE3 may be formed of multiple layers in which one or more inorganic films of silicon nitride (SiNx), silicon oxynitride (SiON), silicon oxide (SiOx), titanium oxide (TiOx), and aluminum oxide (AlOx) layers are alternately stacked.

In some aspects, the encapsulation layer TFE may include at least one organic film TFE2 to protect the display element layer EML from foreign substances such as, for example, dust. The encapsulating organic film TFE2 may be disposed between the first encapsulating inorganic film TFE1 and the second encapsulating inorganic film TFE3. The encapsulation organic film TFE2 may be a monomer. Alternatively, the encapsulation organic film TFE2 may be an organic film such as, for example, acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In some aspects, the adhesive layer ADL may be a transparent adhesive member such as, for example, a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color among light emitted from the third emission area EA3.

The plurality of lenses LNS may be disposed on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic film such as, for example, acrylic resin, epoxy resin, phenolic resin, polyamide resin, or polyimide resin.

The cover layer CVL may be disposed on the filling layer FIL. The cover layer CVL may be a glass substrate or a polymer resin. In an example in which the cover layer CVL is a glass substrate, the cover layer CVL may be attached onto the filling layer FIL. In this case, the filling layer FIL may serve to bond the cover layer CVL. In an example in which the cover layer CVL is a glass substrate, the cover layer CVL may serve as an encapsulation substrate. In an example in which the cover layer CVL is a polymer resin, the cover layer CVL may be directly applied onto the filling layer FIL.

The polarizing plate may be disposed on one surface of the cover layer CVL. The polarizing plate may be a structure for reducing or preventing visibility degradation caused by reflection of external light. The polarizing plate may include a linear polarizing plate and a phase retardation film. For example, the phase retardation film may be a λ/4 plate (quarter-wave plate), but embodiments of the present disclosure are not limited thereto. However, when visibility degradation caused by reflection of external light is sufficiently overcome by the first to third color filters CF1, CF2, and CF3, the polarizing plate may be omitted.

FIG. 10 is a schematic cross-sectional view illustrating another example of the display panel taken along line I1-I1′ illustrated in FIG. 7.

The embodiment of FIG. 10 differs from the embodiment of FIG. 9 in that the first electrode AND of each of the light emitting elements LE is in contact with and electrically connected to the side surface of a connection electrode ANC connected to the eighth conductive layer ML8. The embodiment of FIG. 10 also differs from the embodiment of FIG. 9 in that the trench TRC is omitted, and instead, the third pixel defining film PDL3 and a fourth pixel defining film PDL4 have an eave-shaped or mushroom-shaped cross-sectional structure. In the embodiment of FIG. 10, redundant description of parts already described in the embodiment of FIG. 9 will be omitted.

Referring to FIG. 10, the plurality of connection electrodes ANC may be respectively disposed on first portions AA1 of the ninth interlayer insulating film INS9. Each of the plurality of connection electrodes ANC may be disposed on the first portion AA1 of the ninth interlayer insulating film INS9 corresponding thereto. A plurality of connection electrodes ANC may be formed of any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the plurality of connection electrodes ANC may include titanium (Ti), titanium nitride (TiN), indium tin oxide (ITO), or indium zinc oxide (IZO), but the present disclosure is limited thereto.

A plurality of reflective electrodes RL may be respectively disposed on the plurality of connection electrodes ANC. Each of the plurality of reflective electrodes RL may be disposed on the connection electrode ANC corresponding thereto. The plurality of reflective electrodes RL may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, each of the plurality of reflective electrodes RL may include aluminum (Al) having high reflectivity.

A plurality of optical auxiliary films OAL may be respectively disposed on the plurality of reflective electrodes RL. Each of the plurality of optical auxiliary films OAL may be disposed on the reflective electrode RL corresponding thereto. The plurality of optical auxiliary films OAL may be formed of a silicon oxide (SiOx)-based inorganic film, but embodiments of the present disclosure are not limited thereto.

In each of the first emission area EA1 and the third emission area EA3, a step layer STPL may be disposed on the reflective electrode RL, and the optical auxiliary film OAL may be disposed on the step layer STPL. In the second emission area EA2, the optical auxiliary film OAL (and not the step layer STPL) may be disposed on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary layer OAL may be set in consideration of the wavelength and resonance distance of light emitted from the first stack layer IL1 of the light emitting stack IL, and the wavelength and resonance distance of light emitted from the second stack layer IL2 thereof.

Each of the light emitting elements LE may include the first electrode AND, a light emitting stack IL, and a second electrode CAT.

The first electrode AND of each of the light emitting elements LE may be disposed on the optical auxiliary film OAL corresponding thereto. Since the connection electrode ANC, the reflective electrode RL, and the optical auxiliary layer OAL are sequentially stacked, the first electrode AND of each of the light emitting elements LE may be disposed on the top surface and the side surface of the optical auxiliary layer OAL, the side surface of the reflective electrode RL, and the side surface of the connection electrode ANC. Accordingly, the first electrode AND of each of the light emitting elements LE may be in contact with and electrically connected to the side surface of the reflective electrode RL and the side surface of the connection electrode ANC. Therefore, compared to when the first electrode AND of each of the light emitting elements LE is connected to the reflective electrode RL exposed through a through hole penetrating the optical auxiliary film OAL, the number of mask processes may be reduced, thereby lowering manufacturing cost and increasing manufacturing efficiency.

The first electrode AND of each of the light emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth interlayer insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth interlayer insulating film INS9 may be substantially the same.

Alternatively, the thickness of the first portion AA1 of the ninth interlayer insulating film INS9 may be greater than the thickness of the second portion AA2 thereof. In this case, the side surface of the first portion AA1 of the ninth interlayer insulating film INS9 may be exposed, and the first electrode AND of each of the light emitting elements LE may be disposed on the exposed side surface of the first portion AA1 of the ninth interlayer insulating film INS9.

The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the first electrode AND of each of the light emitting elements LE may include titanium (Ti), titanium nitride (TiN), indium tin oxide (ITO), or indium zinc oxide (IZO), but the present disclosure is limited thereto.

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be disposed on the first electrode AND of each of the light emitting elements LE. Specifically, the first pixel defining film PDL1 may cover a part of the top surface of the first electrode AND disposed on the optical auxiliary film OAL. Further, the first pixel defining film PDL1 may cover the first electrode AND disposed on the side surface of the connection electrode ANC, the side surface of the reflective electrode RL, and the side surface of the optical auxiliary film OAL. The first pixel defining film PDL1 may be disposed on the top surface of the second portion AA2 of the ninth interlayer insulating film INS9.

A planarization film PNS is a film for flattening the stepped portion caused by the connection electrode ANC, the reflective electrode RL, and the optical auxiliary film OAL.

The planarization film PNS may be disposed on the first pixel defining film PDL1 covering the first electrode AND disposed on the side surface of the connection electrode ANC, the side surface of the reflective electrode RL, and the side surface of the optical auxiliary film OAL. The planarization film PNS may be disposed on the first pixel defining film PDL1 disposed on the second portion AA2 of the ninth interlayer insulating film INS9.

The planarization film PNS may be disposed between the connection electrodes ANC adjacent in the first direction DR1 or the second direction DR2. The planarization film PNS may be disposed between the reflective electrodes RL adjacent in the first direction DR1 or the second direction DR2. The planarization film PNS may be disposed between the optical auxiliary films OAL adjacent in the first direction DR1 or the second direction DR2.

The step layer STPL is not present in the second emission area EA2, whereas the step layer STPL is present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 disposed on the top surface of the first electrode AND disposed in the second emission area EA2.

In contrast, the top surface of the planarization film PNS may be flatly connected to the top surface of the first pixel defining film PDL1 disposed on the top surface of the first electrode AND disposed in the first emission area EA1 and the third emission area EA3. That is, the planarization film PNS may not cover the top surface of the first pixel defining film PDL1 disposed on the top surface of the first electrode AND disposed in each of the first emission area EA1 and the third emission area EA3.

The second pixel defining film PDL2 may be disposed on the first pixel defining film PDL1 and the planarization film PNS, the third pixel defining film PDL3 may be disposed on the second pixel defining film PDL2, and the fourth pixel defining film PDL4 may be disposed on the third pixel defining film PDL3. The first pixel defining film PDL1 and the third pixel defining film PDL3 may be formed of a silicon nitride (SiNx)-based inorganic film, whereas the second pixel defining film PDL2, the fourth pixel defining film PDL4, and the planarization film PNS may be formed of a silicon oxide (SiOx)-based inorganic film. The first pixel defining film PDL1 is formed of a material different from a material of the planarization film PNS, and thus may serve as a stopper in a chemical mechanical polishing process for the planarization film PNS.

When the planarization film PNS and the second pixel defining film PDL2 are both formed as a silicon oxide (SiOx)-based inorganic film, the planarization film PNS and the second pixel defining film PDL2 may be formed as a single film.

Since the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. That is, the third pixel defining film PDL3 and the fourth pixel defining film PDL4 may have an eaves-shaped or mushroom-shaped cross-sectional structure.

The light emitting stack IL may be disposed on the first electrode AND and the pixel defining film PDL. The light emitting stack IL may include the first stack layer IL1 and the second stack layer IL2 that emit different lights. In an example in which the light emitting stack IL has a two-tandem structure, one of the first stack layer IL1 and the second stack layer IL2 may emit light that includes the wavelength range of any one of the first light, the second light, and the third light, and the other may emit light that includes the wavelength ranges of the other two lights. For example, the first stack layer IL1 may emit light that includes the wavelength range of the first light and the wavelength range of the third light, and the second stack layer IL2 may emit light that includes the wavelength range of the second light. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be disposed between the first stack layer IL1 and the second stack layer IL2. The charge generation layer may include an n-type charge generation layer that supplies electrons to the first stack layer IL1 and a p-type charge generation layer that supplies holes to the second stack layer IL2. The N-type charge generation layer may include a dopant of a metal material.

The first stack layer IL1 is not formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In this case, the first hole transport layer of the first stack layer IL1, and a charge generation layer disposed between the first stack layer IL1 and the second stack layer IL2 may also be cut off. Further, although FIG. 10 illustrates that the second stack layer IL2 is connected without being cut off, the second hole transport layer of the second stack layer IL2 may be cut off, and the second electron transport layer of the second stack layer IL2 may be connected without being cut off. Therefore, it is possible to prevent a leakage current from flowing through the first hole transport layer of the first stack layer IL1, the second hole transport layer of the second stack layer IL2, and the charge generation layer between the adjacent emission areas EA1, EA2, and EA3. Accordingly, it is possible to prevent the light emitting stack IL in the adjacent emission areas EA1, EA2, and EA3 from emitting light other than the originally intended light due to the influence of the described current.

Although FIG. 10 illustrates a two-tandem structure in which the light emitting stack IL includes two stack layers IL1 and IL2, embodiments of the present disclosure are not limited thereto. For example, the light emitting stack IL may have a three-tandem structure including three stack layers as illustrated in FIG. 9. In this case, the light emitting stack IL may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. Alternatively, as illustrated in FIG. 9, the trench TRC penetrating the first pixel defining film PDL1, the planarization film PNS, the second pixel defining film PDL2, and the third pixel defining film PDL3 may be added. In this case, the trench TRC may penetrate at least a part of the ninth interlayer insulating film INS9, but embodiments of the present disclosure are not limited thereto.

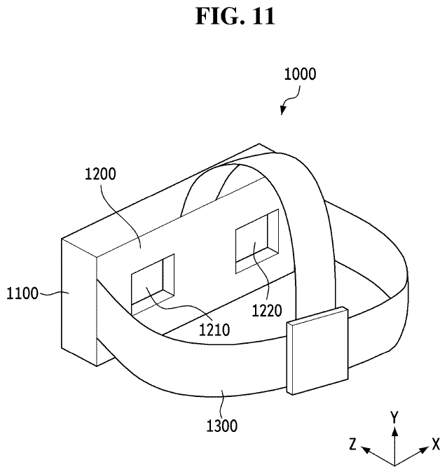

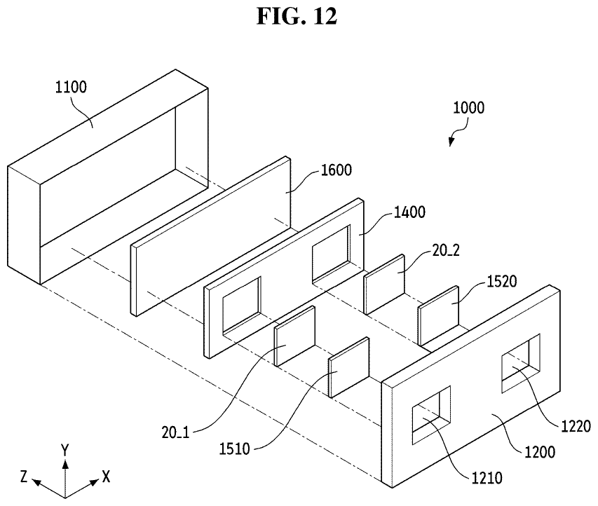

FIG. 11 is a schematic perspective view illustrating one example of a head mounted display. FIG. 12 is a schematic exploded perspective view illustrating the head mounted display illustrated in FIG. 11.

Referring to FIGS. 11 and 12, a head mounted display 1000 according to an embodiment includes a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 provides an image to the user's left eye, and the second display device 20_2 provides an image to the user's right eye. Since each of the first display device 20_1 and the second display device 20_2 is substantially the same as the display device 20 described in conjunction with FIGS. 3 to 10, the description of the first display device 20_1 and the second display device 20_2 will be omitted.

The first optical member 1510 may be disposed between the first display device 20_1 and the first eyepiece 1210. The second optical member 1520 may be disposed between the second display device 20_2 and the second eyepiece 1220. Each of the first optical member 1510 and the second optical member 1520 may include at least one convex lens.

The middle frame 1400 may be disposed between the first display device 20_1 and the control circuit board 1600 and between the second display device 20_2 and the control circuit board 1600. The middle frame 1400 serves to support and fix the first display device 20_1, the second display device 20_2, and the control circuit board 1600.

The control circuit board 1600 may be disposed between the middle frame 1400 and the display device housing 1100. The control circuit board 1600 may be connected to the first display device 20_1 and the second display device 20_2 through the connector. The control circuit board 1600 may convert an image source inputted from the outside into the digital video data DATA, and transmit the digital video data DATA to the first display device 20_1 and the second display device 20_2 through the connector.

The control circuit board 1600 may transmit the digital video data DATA corresponding to a left-eye image optimized for the user's left eye to the first display device 20_1, and may transmit the digital video data DATA corresponding to a right-eye image optimized for the user's right eye to the second display device 20_2. Alternatively, the control circuit board 1600 may transmit the same digital video data DATA to the first display device 20_1 and the second display device 20_2.

The display device housing 1100 serves to accommodate the first display device 20_1, the second display device 20_2, the middle frame 1400, the first optical member 1510, the second optical member 1520, and the control circuit board 1600. The housing cover 1200 is disposed such that the housing cover 1200 covers one open surface of the display device housing 1100. The housing cover 1200 may include the first eyepiece 1210 at which the user's left eye is located and the second eyepiece 1220 at which the user's right eye is located. FIGS. 11 and 12 illustrate that the first eyepiece 1210 and the second eyepiece 1220 are disposed separately, but embodiments of the present disclosure are not limited thereto. The first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520. Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

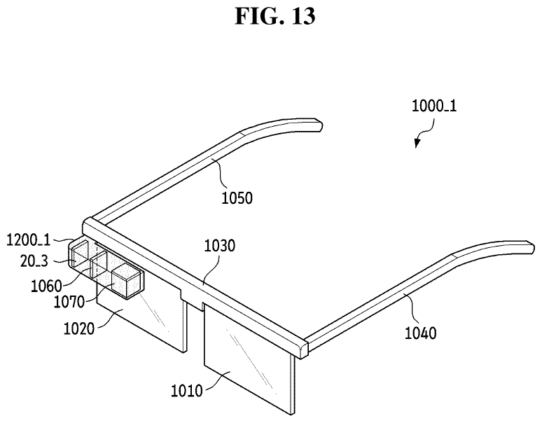

The head mounted band 1300 serves to secure the display device housing 1100 to the user's head such that the first eyepiece 1210 and the second eyepiece 1220 of the housing cover 1200 remain located on the user's left and right eyes, respectively. In an example in which the display device housing 1100 is implemented to be lightweight and compact, the head mounted display 1000 may be provided with, as illustrated in FIG. 13, an eyeglass frame instead of the head mounted band 1300.

FIG. 13 is a schematic perspective view illustrating another example of a head mounted display.

Referring to FIG. 13, a head mounted display 1000_1 according to an embodiment may be an eyeglasses-type display device in which a display device housing 1200_1 is implemented in a lightweight and compact manner. The head mounted display 1000_1 according to an embodiment may include a display device 20_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 20_3, the optical member 1060, and the optical path changing member 1070. The image displayed on the display device 20_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 20_3 and a real image seen through the right eye lens 1020 are combined.

FIG. 13 illustrates that the display device housing 1200_1 is disposed at the right end of the support frame 1030, but embodiments of the present disclosure are not limited thereto. For example, the display device housing 1200_1 may be disposed at the left end of the support frame 1030, and in this case, the image of the display device 20_3 may be provided to the user's left eye. Alternatively, the display device housing 1200_1 may be disposed at both the left and right ends of the support frame 1030, and in this case, the user may view the image displayed on the display device 20_3 through both the left and right eyes.

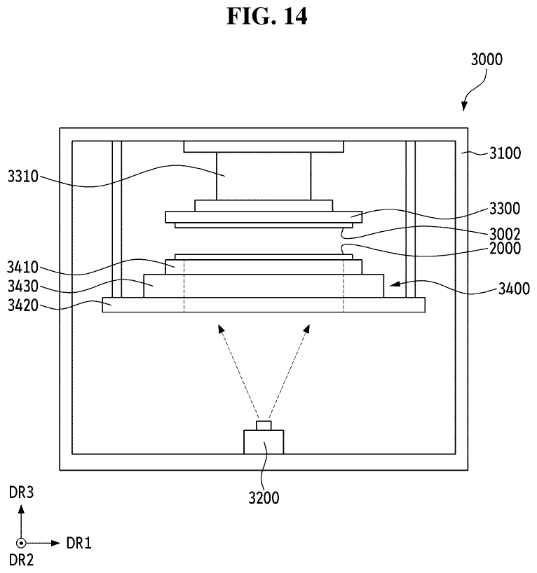

FIG. 14 is a schematic diagram illustrating a deposition mask and a deposition apparatus including the deposition mask according to an embodiment of the present disclosure.

Referring to FIG. 14, a deposition apparatus 3000 may be used to form light emitting material layers on a backplane substrate 3002 in a manufacturing process of the display panel 100 (see FIG. 3). For example, as illustrated in FIG. 9, the semiconductor backplane SBP and the light emitting element backplane EBP may be disposed on the backplane substrate 3002, and the reflective electrode layer RL and the insulating films INS10 and INS11 may be disposed on the light emitting element backplane EBP. Electrode patterns, for example, the anode electrodes AND may be disposed on the insulating film INS11, and the anode electrodes AND may be electrically connected to the reflective electrode layer RL through the vias VA10. As an example, the deposition apparatus 3000 may form first light emitting layers on the anode electrodes AND of first emission areas EA1. As another example, the deposition apparatus 3000 may form second light emitting layers on the anode electrodes AND of second emission areas EA2. As still another example, the deposition apparatus 3000 may form third light emitting layers on the anode electrodes AND of third emission areas EA3.

The deposition apparatus 3000 may include a deposition source 3200 for providing a vapor deposition material on the backplane substrate 3002, a deposition mask 2000 disposed above the deposition source 3200, and a substrate chuck 3300 disposed above the deposition mask 2000 to support the backplane substrate 3002 such that the backplane substrate 3002 faces the deposition mask 2000. That is, the substrate chuck 3300 may support the backplane substrate 3002 such that the front surface of the backplane substrate 3002 faces downward, and may locate the backplane substrate 3002 above the deposition mask 2000 to perform a deposition process.

The deposition source 3200, the deposition mask 2000, and the substrate chuck 3300 may be disposed in a process chamber 3100. The process chamber 3100 may have an internal space, and a deposition process for forming deposition material layers on the backplane substrate 3002 may be performed in the internal space of the process chamber 3100. Although not illustrated, the process chamber 3100 may be connected to a vacuum pump (not illustrated), and the internal space of the process chamber 3100 may be set to a vacuum atmosphere by the vacuum pump. An opening (not illustrated) for the carry-in and carry-out of the backplane substrate 3002 and the deposition mask 2000 may be provided in a wall of the process chamber 3100, and the opening may be opened and closed by a gate valve (not illustrated).

A deposition material may be accommodated in the deposition source 3200. The deposition source 3200 may evaporate a deposition material such as, for example, an organic material, an inorganic material, a conductive material, or the like toward the backplane substrate 3002, and the evaporated deposition material may be deposited on the backplane substrate 3002 through the deposition mask 2000. For example, the deposition source 3200 may evaporate an organic material for forming light emitting material layers on the backplane substrate 3002, and the evaporated organic material may be deposited on the electrode patterns on the backplane substrate 3002 through the deposition mask 2000.

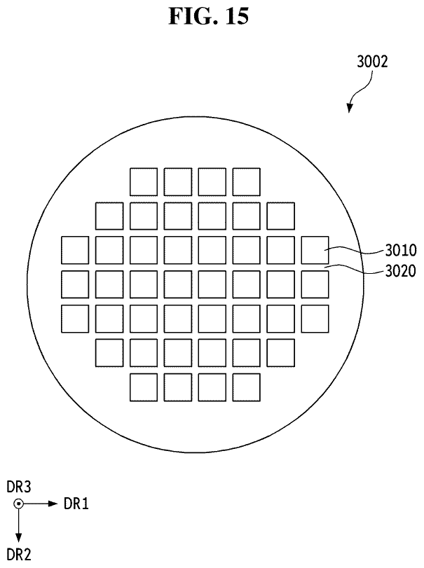

FIG. 15 is a schematic bottom view illustrating the backplane substrate illustrated in FIG. 14.

Referring to FIG. 15, the backplane substrate 3002 may include a plurality of display cell regions 3010 and a scribe lane region 3020 disposed between the display cell regions 3010. The display cell regions 3010 may be arranged in a matrix form along the first direction DR1 and the second direction DR2 as illustrated in FIG. 15, and may be individualized into display panels 100 (see FIG. 3) by a dicing process after the display manufacturing process is completed. For example, the first direction DR1 may be a first horizontal direction, and the second direction DR2 may be a second horizontal direction perpendicular to the first direction DR1. In some aspects, each of the display cell regions 3010 may have, for example, a quadrilateral shape as illustrated in the drawing.

For example, each of the display cell regions 3010 may include the semiconductor backplane SBP, the light emitting element backplane EBP disposed on the semiconductor backplane SBP, the reflective electrode layer RL disposed on the light emitting element backplane EBP, and the insulating films INS10 and INS11 disposed on the reflective electrode layer RL as illustrated in FIG. 9. In some aspects, each of the display cell regions 3010 may include the plurality of electrode patterns, for example, the plurality of anode electrodes AND disposed on the insulating film INS11, and the anode electrodes AND may be connected to the reflective electrode layer RL through the plurality of vias VA10. In this case, the electrode patterns of the display cell regions 3010 may be disposed on the front surface of the backplane substrate 3002, and the substrate chuck 3300 may hold the rear surface of the backplane substrate 3002 such that the electrode patterns of the display cell regions 3010 face downward, i.e., face the deposition source 3200.

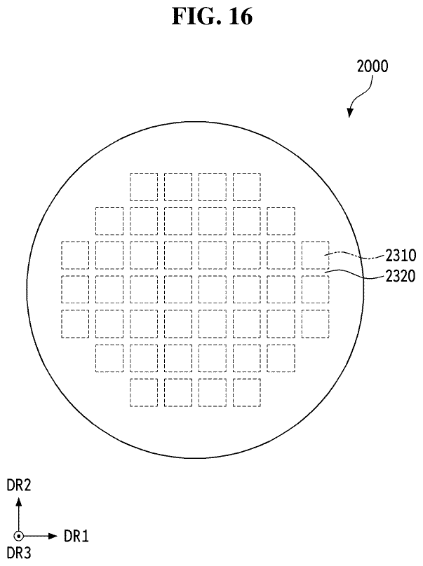

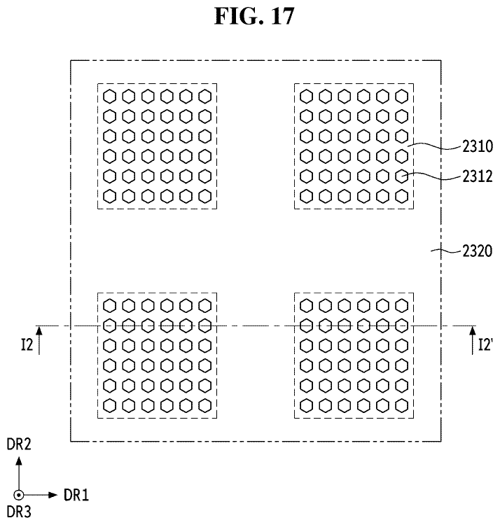

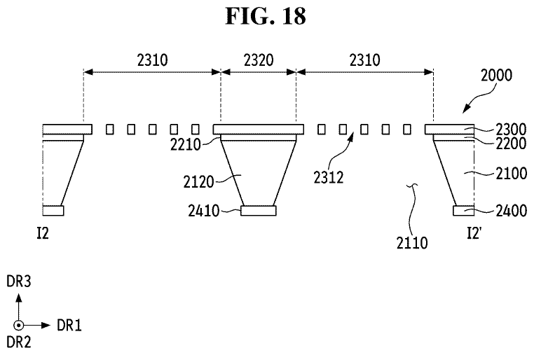

FIG. 16 is a schematic plan view illustrating the deposition mask illustrated in FIG. 14. FIG. 17 is a schematic enlarged plan view illustrating the mask cell regions illustrated in FIG. 16. FIG. 18 is a schematic cross-sectional view taken along line I2-I2′ illustrated in FIG. 17.

Referring to FIGS. 16 to 18, the deposition mask 2000 may include mask cell regions 2310 respectively corresponding to the display cell regions 3010 of the backplane substrate 3002. Each of the mask cell regions 2310 may have a plurality of pixel openings 2312 exposing the anode electrodes AND in the deposition process. For example, the deposition mask 2000 may include a mask frame 2100, an intermediate inorganic film 2200 disposed on the mask frame 2100, and a membrane 2300 disposed on the intermediate inorganic film 2200. In this case, the membrane 2300 may include a plurality of mask cell regions 2310, and each of the mask cell regions 2310 may have a plurality of pixel openings 2312.

For example, the mask frame 2100 may have cell openings 2110 and include a rib region 2120 defining the cell openings 2110. The membrane 2300 may include mask cell regions 2310 respectively disposed on the cell openings 2110, and a grid region 2320 surrounding the mask cell regions 2310. That is, the grid region 2320 of the membrane 2300 may be disposed on the rib region 2120 of the mask frame 2100. The mask cell regions 2310 may be exposed toward the deposition source 3200 through the cell openings 2110, and the pixel openings 2312 may be formed to penetrate the mask cell regions 2310. That is, the pixel openings 2312 may communicate with the cell openings 2110. In this case, while performing the deposition process, the vapor deposition material provided from the deposition source 3200 may be deposited on the anode electrodes AND of the backplane substrate 3002 through the cell openings 2110 and the pixel openings 2312.

As illustrated in FIG. 16, the mask cell regions 2310 may be arranged in a matrix form along the first direction DR1 and the second direction DR2. For example, the first direction DR1 may be the first horizontal direction, and the second direction DR2 may be the second horizontal direction perpendicular to the first direction DR1. In this case, the third direction DR3 may be a vertical direction. That is, the third direction DR3 may be a direction perpendicular to the first direction DR1 and the second direction DR2. For example, the third direction DR3 may be a thickness direction of the mask frame 2100. The mask cell regions 2310 may have, for example, a quadrilateral shape as illustrated in the drawing, and the pixel openings 2312 may be arranged to correspond to the anode electrodes AND of any of the first emission areas EA1, the second emission areas EA2, and the third emission areas EA3.

According to one or more embodiments of the present disclosure, the intermediate inorganic film 2200 may be disposed between the mask frame 2100 and the membrane 2300. That is, the intermediate inorganic film 2200 may be disposed between the rib region 2120 of the mask frame 2100 and the grid region 2320 of the membrane 2300. For example, the intermediate inorganic film 2200 and the membrane 2300 may be disposed on the front surface of the mask frame 2100, and a rear inorganic film 2400 may be disposed on the rear surface of the mask frame 2100.

The mask frame 2100 may be formed of single crystal silicon. For example, a single crystal silicon substrate having a thickness in the range of about 700 μm to about 800 μm, e.g., about 775 μm, may be used as the mask frame 2100. The membrane 2300 may be formed of silicon nitride (SiNx) and may be formed to have a thickness ranging from about 0.5 μm to about 3 μm, for example, about 1 μm, through a thermal chemical vapor deposition (TCVD) process. The rear inorganic film 2400 may be formed of silicon nitride (SiNx) and may be formed through a TCVD process. For example, the membrane 2300 and the rear inorganic film 2400 may be formed simultaneously through a TCVD process. Descriptions herein of an element (e.g., membrane 2300, intermediate inorganic film 2200, or the like) being formed to have a particular thickness may refer to forming the element such that the element has the particular thickness.

The intermediate inorganic film 2200 may be formed of a material having etching selectivity with respect to the membrane 2300 and the rear inorganic film 2400. According to one or more embodiments of the present disclosure, the intermediate inorganic film 2200 may be formed of a material containing germanium (Ge), and may be formed to have a thickness ranging from about 50 nm to about 1 μm, e.g., about 0.5 μm, through an epitaxial growth process, an electron beam evaporation process, a low pressure chemical vapor deposition (LPCVD) process, a plasma enhanced chemical vapor deposition (PECVD) process, or the like. For example, the intermediate inorganic film 2200 may be formed of amorphous germanium (Ge), single crystal germanium (Ge), polycrystalline germanium (Ge), or silicon germanium (SiGe).

As another example, the intermediate inorganic film 2200 may be formed of boron-doped germanium (Ge:B) or boron-doped silicon germanium (SiGe:B). In this case, the intermediate inorganic film 2200 may be formed by an epitaxial growth process, and the lattice constant of the intermediate inorganic film 2200 may be reduced by boron doping. Specifically, the lattice constant of silicon (Si) is 5.43 Å and the lattice constant of germanium (Ge) is 5.66 Å. Therefore, when the intermediate inorganic film 2200 is formed of germanium (Ge) or silicon germanium (SiGe), residual compressive stress may be generated in the intermediate inorganic film 2200 due to the difference in lattice constant between the mask frame 2100 and the intermediate inorganic film 2200. However, when the intermediate inorganic film 2200 is formed of boron-doped germanium (Ge:B) or boron-doped silicon germanium (SiGe:B), the difference in lattice constant may be reduced, such that the residual compressive stress of the intermediate inorganic film 2200 may be reduced.

The pixel openings 2312 of the membrane 2300 may be formed through an anisotropic etching process. For example, after forming on the membrane 2300 a first photoresist pattern (not illustrated) exposing the portions where the pixel openings 2312 are to be formed, an anisotropic etching process, for example, a reactive ion etching (RIE) process, using the first photoresist pattern as an etching mask may be performed to form the pixel openings 2312 penetrating the membrane 2300. In this case, the intermediate inorganic film 2200 may be used as an etch stop film in the anisotropic etching process, and the first photoresist pattern may be removed through a stripping and/or ashing process after the pixel openings 2312 are formed.

The rear inorganic film 2400 may have rear openings 2410 corresponding to the cell openings 2110 of the mask frame 2100, and may function as an etching mask in an etching process for forming the cell openings 2110 of the mask frame 2100. For example, after forming on the rear inorganic film 2400 a second photoresist pattern (not illustrated) exposing the portions where the rear openings 2410 are to be formed, an anisotropic etching process, for example, a RIE process may be performed using the second photoresist pattern as an etching mask to form the rear openings 2410 that penetrate the rear inorganic film 2400. The second photoresist pattern may be removed through a stripping and/or ashing process after the rear openings 2410 are formed.

The cell openings 2110 of the mask frame 2100 may be formed through an anisotropic etching process using the rear inorganic film 2400 as an etching mask. According to one or more embodiments of the present disclosure, the cell openings 2110 of the mask frame 2100 may be formed by a first wet etching process using an etchant containing potassium hydroxide (KOH). For example, an etchant containing about 10 wt % to about 40 wt % of KOH and water (H₂O) (hereinafter, referred to as “KOH solution”) may be used, and isopropyl alcohol (IPA) may be added as a surfactant.

The first wet etching process may be performed until the intermediate inorganic film 2200 is exposed. In this case, the intermediate inorganic film 2200 may be used as an etch stop film in the first wet etching process, and, accordingly, the cell openings 2110 may be formed from the rear surface of the mask frame 2100 toward the front surface of the mask frame 2100. That is, the intermediate inorganic film 2200 may prevent the KOH solution from being provided onto the front surface of the mask frame 2100 through the pixel openings 2312 of the membrane 2300.

The membrane 2300 formed of silicon nitride (SiNx) and the intermediate inorganic film 2200 containing germanium (Ge) may be hardly removed by the KOH solution. That is, the etching rates of the membrane 2300 and the intermediate inorganic film 2200 by the KOH solution are negligible (e.g., less than a threshold etching rate), and, thus, damage to the membrane 2300 may be prevented during the first wet etching process.

Hydrogen (H₂) bubbles may be generated by a reaction between the silicon of the mask frame 2100 and the KOH solution during the first wet etching process. For example, if there exists no intermediate inorganic film 2200 between the mask frame 2100 and the membrane 2300, the KOH solution may be provided onto the front surface of the mask frame 2100 through the pixel openings 2312. In this case, hydrogen (H₂) bubbles may be generated in the pixel openings 2312, and the membrane 2300 may be damaged by these hydrogen (H₂) bubbles. However, according to an embodiment of the present disclosure, the intermediate inorganic film 2200 may prevent the KOH solution from being provided onto the front surface of the mask frame 2100 through the pixel openings 2312. Therefore, damage to the membrane 2300 may be prevented when the wet etching process described herein is performed.

In the first wet etching process using the KOH solution, the etching rate may be controlled by the temperature of the KOH solution. According to one or more embodiments of the present disclosure, the first wet etching process described herein may be performed at a temperature ranging from about 40° C. to about 100° C. When the cell openings 2110 are formed through a wet etching process using a TMAH solution, a long processing time of about 24 hours to about 25 hours may be required. According to one or more embodiments of the present disclosure, however, when the cell openings 2110 are formed using the KOH solution, a processing time may be shortened to about 6 hours or less, for example, about 3 hours to about 4 hours, by properly controlling the concentration of the KOH and the temperature of the KOH solution.

In some embodiments, the <100> crystal direction of the monocrystalline silicon substrate used as the mask frame 2100 may be the third direction DR3, such that the cell openings 2110 may be formed to have a width that gradually decreases toward the membrane 2300, i.e., in the third direction DR3, by the first wet etching process. For example, the inner surfaces of the cell openings 2110 may be formed to have an inclination of about 54.74°.

After the cell openings 2110 of the mask frame 2100 are formed, the portions of the intermediate inorganic film 2200 exposed by the cell openings 2110 may be removed by a second wet etching process, such that the cell openings 2110 of the mask frame 2100 communicate with the pixel openings 2312 of the membrane 2300. Specifically, the cell openings 2110 of the mask frame 2100 may communicate with the pixel openings 2312 of the membrane 2300 due to the second wet etching process, and intermediate openings 2210 penetrating the intermediate inorganic film 2200 may be formed by the second wet etching process. That is, the intermediate openings 2210 connecting the cell openings 2110 to the pixel openings 2312 may be formed by the second wet etching process.

For example, the portions of the intermediate inorganic film 2200 exposed by the cell openings 2110 may be removed using an etchant containing hydrofluoric acid (HF), hydrogen peroxide (H₂O₂), acetic acid (CH₃COOH), and water (H₂O). As another example, the portions of the intermediate inorganic film 2200 exposed by the cell openings 2110 may be removed using an etchant containing ammonium hydroxide (NH₄OH), hydrogen peroxide (H₂O₂), and water (H₂O). In this case, a standard cleaning solution (SC-1) with a mixing ratio of ammonium hydroxide (NH₄OH), hydrogen peroxide (H₂O₂), and water (H₂O) of 1:5:1, or an etchant with a mixing ratio of ammonium hydroxide (NH₄OH), hydrogen peroxide (H₂O₂), and water (H₂O) of 1:5:20 may be used, and the etchant may further contain peroxyacetic acid (CH₃COOOH), acetic acid (CH₃COOH), hydrofluoric acid (HF), and/or a surfactant. In some aspects, the second wet etching process may be performed at a temperature ranging from about 40° C. to about 80° C.

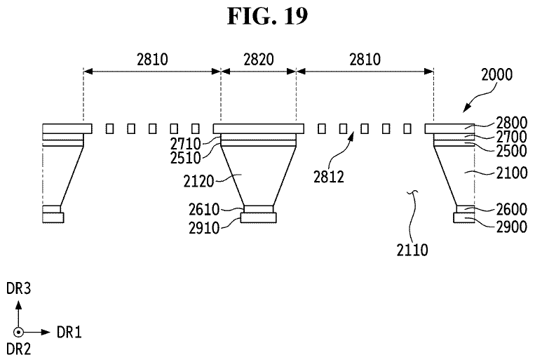

FIG. 19 is a cross-sectional view illustrating a deposition mask according to another embodiment of the present disclosure.

Referring to FIG. 19, the deposition mask 2000 according to another embodiment of the present disclosure may include the mask frame 2100 having the cell openings 2110, an intermediate inorganic film 2700 disposed on the mask frame 2100, and a membrane 2800 disposed on the intermediate inorganic film 2700. The membrane 2800 may include mask cell regions 2810 respectively disposed on the cell openings 2110, and each of the mask cell regions 2810 may have a plurality of pixel openings 2812. The mask frame 2100 may include the rib region 2120 defining the cell openings 2110, and the membrane 2800 may include a grid region 2820 disposed on the rib region 2120.

According to the present embodiment, the deposition mask 2000 may include a buffer inorganic film 2500 disposed between the mask frame 2100 and the intermediate inorganic film 2700. For example, the buffer inorganic film 2500 may be formed of silicon oxide (SiOx), and may be formed to have a thickness ranging from about 0.5 μm to about 2 μm through a thermal oxidation process. That is, the buffer inorganic film 2500 may be disposed on the mask frame 2100, and the intermediate inorganic film 2700 may be disposed on the buffer inorganic film 2500.

The intermediate inorganic film 2700 may be formed of a material containing germanium (Ge). For example, the intermediate inorganic film 2700 may be formed to have a thickness ranging from about 50 nm to about 1 μm, e.g., about 0.5 μm, through an electron beam evaporation process, an LPCVD process, a PECVD process, or the like, and may be formed of amorphous germanium (Ge), polycrystalline germanium (Ge), or silicon germanium (SiGe). The membrane 2800 may be formed of silicon nitride (SiNx), and may be formed to have a thickness ranging from about 0.5 μm to about 3 μm, e.g., a thickness of about 1 μm, through a TCVD process.

The buffer inorganic film 2500, the intermediate inorganic film 2700 and the membrane 2800 may be disposed on the front surface of the mask frame 2100, and a first rear inorganic film 2600 and a second rear inorganic film 2900 may be disposed on the rear surface of the mask frame 2100. For example, the first rear inorganic film 2600 may be formed simultaneously with the buffer inorganic film 2500 through a thermal oxidation process, and the second rear inorganic film 2900 may be formed simultaneously with the membrane 2800 through a TCVD process. The first rear inorganic film 2600 and the second rear inorganic film 2900 may have first rear openings 2610 and second rear openings 2910, respectively, and may function as an etching mask in an etching process for forming the cell openings 2110.

The buffer inorganic film 2500 and the first rear inorganic film 2600 may be used to reduce stress that is applied to the mask frame 2100 by the intermediate inorganic film 2700, the membrane 2800, and the second rear inorganic film 2900. For example, the membrane 2800 and the second rear inorganic film 2900 may have residual tensile stress, and the intermediate inorganic film 2700 may have residual compressive stress. The buffer inorganic film 2500 and the first rear inorganic film 2600 may be formed to have a residual compressive stress smaller than a residual compressive stress of the intermediate inorganic film 2700 so as to relieve stresses applied to the mask frame 2100 by the intermediate inorganic film 2700, the membrane 2800, and the second rear inorganic film 2900.

The etching process for forming the cell openings 2110 of the mask frame 2100 may be performed until the buffer inorganic film 2500 is exposed, and in this case, the intermediate inorganic film 2700 and the buffer inorganic film 2500 may prevent an etchant, that is, a KOH solution, from being provided onto the front surface of the mask frame 2100 through the pixel openings 2812. Th portions of the buffer inorganic film 2500 exposed by the cell openings 2110 after the cell openings 2110 are formed may be removed by a third wet etching process using an etchant such as, for example, diluted hydrofluoric acid (HF) or buffered oxide etchant (BOE), and front openings 2510 penetrating the buffer inorganic film 2500 may be formed by the third etching process.

The front openings 2510 of the buffer inorganic film 2500 may partially expose the intermediate inorganic film 2700, and the portions of the intermediate inorganic film 2700 exposed by the front openings 2510 may be removed by the second wet etching process. Intermediate openings 2710 penetrating the intermediate inorganic film 2700 may be formed by the second wet etching process, and the mask cell regions 2810 may be exposed by the intermediate openings 2710. As a result, the pixel openings 2812 may be connected to the cell openings 2110 through the intermediate openings 2710 and the front openings 2510.

In the present embodiment, the other elements, except for the buffer inorganic film 2500 and the first rear inorganic film 2600, are substantially the same as those described herein with reference to FIGS. 16 to 18. Therefore, further descriptions thereof will be omitted.

Referring back to FIG. 14, the substrate chuck 3300 may be disposed above the deposition source 3200 and may support the backplane substrate 3002, such that the backplane substrate 3002 faces the deposition source 3200. For example, the substrate chuck 3300 may be an electrostatic chuck configured to hold the rear surface of the backplane substrate 3002 using an electrostatic force. To elaborate, the electrode patterns, i.e., the anode patterns AND may be disposed on the front surface of the backplane substrate 3002, and the substrate chuck 3300 may hold the rear surface of the backplane substrate 3002 such that the front surface of the backplane substrate 3002 faces the deposition source 3200, i.e., faces downward.

Although not illustrated, the backplane substrate 3002 may be loaded into the process chamber 3100 by a transfer robot, and lift fingers (not illustrated) for transferring the backplane substrate 3002 from the transfer robot to the substrate chuck 3300 may be disposed in the process chamber 3100. For example, the backplane substrate 3002 may be placed on the lift fingers after being brought into the process chamber 3100 by the transfer robot, and the lift fingers may be raised to load the backplane substrate 3002 on the substrate chuck 3300. Subsequently, the substrate chuck 3300 may hold the rear surface of the backplane substrate 3002 by using the electrostatic force.

An upper driving unit 3310 for moving and rotating the substrate chuck 3300 may be disposed above the substrate chuck 3300 to adjust the position and angle of the backplane substrate 3002. For example, the upper driving unit 3310 may move the substrate chuck 3300 in the first and second directions DR1 and DR2 to adjust the horizontal position of the backplane substrate 3002, and may move the substrate chuck 3300 in the third direction DR3 to adjust the vertical position of the backplane substrate 3002. In this case, the first direction DR1, the second direction DR2, and the third direction DR3 may be an X-axis direction, a Y-axis direction, and a Z-axis direction, respectively.

In some aspects, the upper driving unit 3310 may rotate the substrate chuck 3300 around the Z-axis to adjust the azimuthal angle of the backplane substrate 3002. Further, in order to adjust the inclination of the backplane substrate 3002, the upper driving unit 3310 may rotate the substrate chuck 3300 around the X-axis, and may rotate the substrate chuck 3300 around the Y-axis. For example, the upper driving unit 3310 may include a hexapod actuator that provides a motion of 6 degrees of freedom (X, Y, Z, θx, θy, and θz).

A mask stage 3400 on which the deposition mask 2000 is placed may be disposed above the deposition source 3200. That is, the mask stage 3400 may be disposed under the substrate chuck 3300 and may support an edge portion of the deposition mask 2000. The deposition mask 2000 may be carried into the process chamber 3100 by the transfer robot. For example, the deposition mask 2000 brought into the process chamber 3100 by the transfer robot may be placed on the lift fingers, and the lift fingers may be lowered to load the deposition mask 2000 on the mask stage 3400.

The mask stage 3400 may include a mask chuck 3410 for supporting the deposition mask 2000. Although not illustrated in detail, the mask chuck 3410 may have a circular ring shape and support the edge portion of the deposition mask 2000. For example, the mask chuck 3410 may be an electrostatic chuck configured to hold the edge portion of the deposition mask 2000 using an electrostatic force.

The mask stage 3400 may include a support plate 3420 for supporting the mask chuck 3410. The support plate 3420 may have an opening which may expose the mask cell regions 2310 of the deposition mask 2000 toward the deposition source 3200, and a lower driving unit 3430 for adjusting the position and angle of the deposition mask 2000 may be disposed between the support plate 3420 and the mask chuck 3410. For example, the lower driving unit 3430 may move the mask chuck 3410 in the first and second directions DR1 and DR2 to adjust the horizontal position of the deposition mask 2000, and may rotate the mask chuck 3410 around the Z-axis to adjust the azimuthal angle of the deposition mask 2000. As an example, the lower driving unit 3430 may include a piezo actuator that provides a motion of 3 degrees of freedom (X, Y, and θz), and the piezo actuator may have a quadrilateral ring shape.

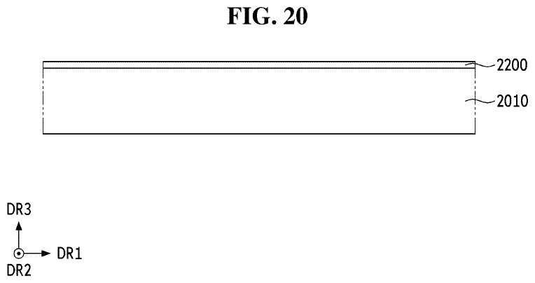

FIGS. 20 to 25 are schematic cross-sectional views illustrating a method of manufacturing a deposition mask according to still another embodiment of the present disclosure.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” “may be patterned,” and the like include methods, processes, and techniques for disposing, forming, patterning, and the like in accordance with example aspects described herein.

Referring to FIG. 20, the method may include forming the intermediate inorganic film 2200 on a mask substrate 2010. For example, a single crystal silicon substrate may be used as the mask substrate 2010, and the mask substrate 2010 may function as the mask frame 2100 of the deposition mask 2000.

The intermediate inorganic film 2200 may be formed of a material containing germanium (Ge). For example, the intermediate inorganic film 2200 may be formed to have a thickness ranging from about 50 nm to about 1 μm, e.g., about 0.5 μm, through an epitaxial growth process, an electron beam evaporation process, an LPCVD process, a PECVD process, or the like. For example, the intermediate inorganic film 2200 may be formed of amorphous germanium (Ge), single crystal germanium (Ge), polycrystalline germanium (Ge), or silicon germanium (SiGe). For example, the intermediate inorganic film 2200 may be formed through an LPCVD process using a germanium source gas such as, for example, GeH₄, GeF₄, Ge₂H₆, or the like. As another example, when the intermediate inorganic film 2200 contains silicon germanium (SiGe), a germanium source gas such as, for example, GeH₄, GeF₄, Ge₂H₆, or the like and a silicon source gas such as, for example, SiH₄, Si₂H₆, SiH₂Cl₂, or the like may be used.

As still another example, the intermediate inorganic film 2200 may be formed of boron-doped germanium (Ge:B) or boron-doped silicon germanium (SiGe:B). In this case, the intermediate inorganic film 2200 may be formed by an epitaxial growth process, and the lattice constant of the intermediate inorganic film 2200 may be reduced by boron doping. By way of example, the intermediate inorganic film 2200 may be formed through an epitaxial growth process using a silicon source gas such as, for example, SiH₄, Si₂H₆, SiH₂Cl₂, or the like, a germanium source gas such as, for example, GeH₄, GeF₄, Ge₂H₆, or the like, and a boron doping gas such as, for example, B₂H₆. Specifically, the lattice constant of silicon (Si) is 5.43 Å and the lattice constant of germanium (Ge) is 5.66 Å. Therefore, when the intermediate inorganic film 2200 is formed of germanium (Ge) or silicon germanium (SiGe), residual compressive stress may be generated in the intermediate inorganic film 2200 due to the difference in lattice constant between the mask substrate 2010 and the intermediate inorganic film 2200. However, when the intermediate inorganic film 2200 is formed of boron-doped germanium (Ge:B) or boron-doped silicon germanium (SiGe:B) in accordance with one or more embodiments of the present disclosure, the difference in lattice constant may be reduced, such that the residual compressive stress of the intermediate inorganic film 2200 may be reduced.

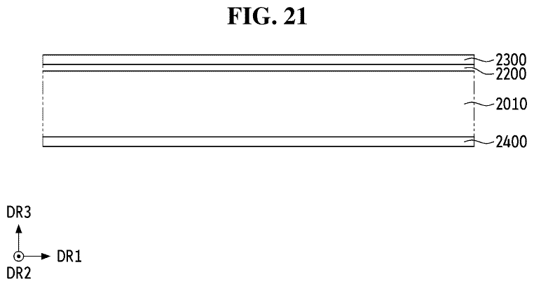

Referring to FIG. 21, the method may include forming the membrane 2300 on the intermediate inorganic film 2200. The membrane 2300 may be formed of silicon nitride (SiNx), and may be formed to have a thickness ranging from about 0.5 μm to about 3 μm through a TCVD process. For example, the membrane 2300 may be formed by a reaction between a silicon source gas such as, for example, SiH₄, Si₂H₆, SiH₂Cl₂, or the like and a nitrogen source gas such as, for example, ammonia (NH₃).

The method may include forming the intermediate inorganic film 2200 and the membrane 2300 on the front surface of the mask substrate 2010, and the method may include forming the rear inorganic film 2400 on the rear surface of the mask substrate 2010. For example, the rear inorganic film 2400 may be formed simultaneously with the membrane 2300 by a TCVD process, and may be formed of the same material as the membrane 2300.

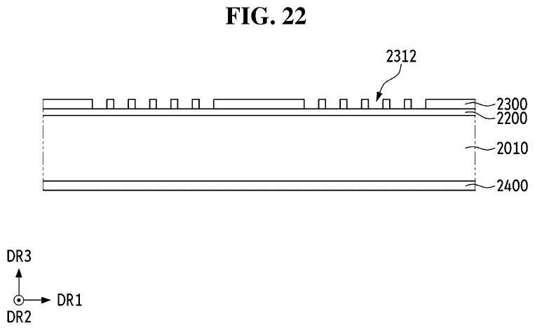

Referring to FIG. 22, the method may include patterning the membrane 2300 to form the plurality of pixel openings 2312 that partially expose the intermediate inorganic film 2200. For example, after forming on the membrane 2300 a first photoresist pattern (not illustrated) exposing the portions where the pixel openings 2312 are to be formed, the method may include performing an anisotropic etching process using the first photoresist pattern as an etching mask to form the pixel openings 2312 that expose the intermediate inorganic film 2200. For example, the pixel openings 2312 may be formed by an RIE process using a reaction gas such as, for example, CHF₃, CH₃F, CH₂F₂, CHF₆, CF₄, C₂F₆, C₃F₆, or the like and a sputtering gas such as, for example, Ar, O₂/Ar, or the like. In this case, the intermediate inorganic film 2200 may function as an etch stop film in the RIE process. The first photoresist pattern may be removed through a stripping and/or ashing process after the pixel openings 2312 are formed.

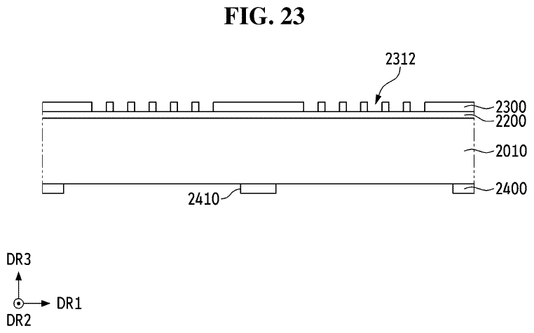

Referring to FIG. 23, the method may include patterning the rear inorganic film 2400 to form the rear openings 2410. For example, after forming on the rear inorganic film 2400 a second photoresist pattern (not illustrated) exposing the portions where the rear openings 2410 are to be formed, the method may include performing an anisotropic etching process, such as, for example, an RIE process, using the second photoresist pattern as an etching mask. The anisotropic etching process may be performed until rear portions of the mask substrate 2010 are exposed. In this case, the rear openings 2410 may overlap the plurality of pixel openings 2312 in the third direction DR3. That is, the rear openings 2410 may expose the rear portions of the mask substrate 2010 where the cell openings 2110 are to be formed. The second photoresist pattern may be removed through a stripping and/or ashing process after the rear openings 2410 are formed.

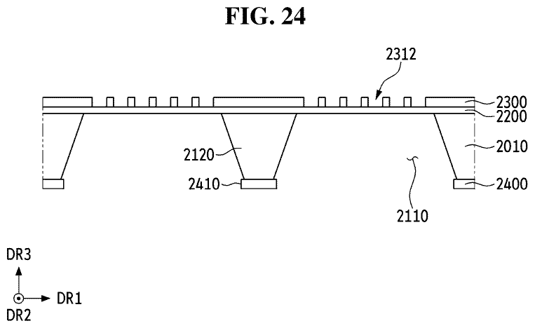

Referring to FIG. 24, the method may include patterning the mask substrate 2010 to form the cell openings 2110 that partially expose the intermediate inorganic film 2200. For example, the method may include performing a first wet etching process using the rear inorganic film 2400 as an etching mask. The mask substrate 2010 may be partially removed by the first wet etching process, and, as a result, the cell openings 2110 partially exposing the intermediate inorganic film 2200 may be formed. That is, the rib region 2120 defining the cell openings 2110 may be formed by the first wet etching process.

According to the present embodiment, in the first wet etching process, a KOH solution may be used as an etchant, and isopropyl alcohol (IPA) may be added to the etchant as a surfactant. The method may include performing the first wet etching process until the intermediate inorganic film 2200 is exposed. In this case, the intermediate inorganic film 2200 may be used as an etch stop film in the first wet etching process, and, accordingly, the cell openings 2110 may be formed from the rear surface of the mask substrate 2010 toward the front surface of the mask substrate 2010. That is, the intermediate inorganic film 2200 may prevent the KOH solution from being provided onto the front surface of the mask substrate 2010 through the pixel openings 2312 of the membrane 2300.

The membrane 2300 formed of silicon nitride (SiNx) and the intermediate inorganic film 2200 containing germanium (Ge) may be hardly removed by the KOH solution. That is, the etching rates of the membrane 2300 and the intermediate inorganic film 2200 by the KOH solution are negligible (i.e., less than a threshold etching rate), and, thus, damage to the membrane 2300 may be prevented during the first wet etching process.

Hydrogen (H₂) bubbles may be generated by a reaction between the silicon of the mask substrate 2010 and the KOH solution during the first wet etching process. For example, if there exists no intermediate inorganic film 2200 between the mask substrate 2010 and the membrane 2300, the KOH solution may be provided onto the front surface of the mask substrate 2010 through the pixel openings 2312. In this case, hydrogen (H₂) bubbles may be generated in the pixel openings 2312, and the membrane 2300 may be damaged by these hydrogen (H₂) bubbles. However, according to an embodiment of the present disclosure, the intermediate inorganic film 2200 may prevent the KOH solution from being provided onto the front surface of the mask substrate 2010 through the pixel openings 2312. Therefore, damage to the membrane 2300 may be prevented when the wet etching process described herein is performed.

In some cases, during the first wet etching process, a difference in etching rate may occur between various portions of the mask substrate 2010, for example, between a central portion and edge portions thereof. In this case, while the cell openings 2110 are being formed in portions with a relatively low etching rate, the intermediate inorganic film 2200 may be exposed to the KOH solution through the cell openings 2110 that are formed first in portions with a relatively high etching rate. According to the present embodiment, however, the intermediate inorganic film 2200 is hardly etched by the KOH solution. Thus, even if there occurs a difference in etching rate between various portions of the mask substrate 2010, damage to the membrane 2300 by hydrogen (H₂) bubbles may be prevented.

In the first wet etching process, the etching rate may be controlled by the temperature of the KOH solution. For example, the first wet etching process may be performed at a temperature ranging from about 40° C. to about 100° C. According to the present embodiment, the amount of time for performing the first wet etching process (i.e., the duration of the first wet etching process) may be reduced to about 6 hours or less, e.g., about 3 hours to about 4 hours, by appropriately controlling the concentration of KOH and the temperature of the KOH solution.

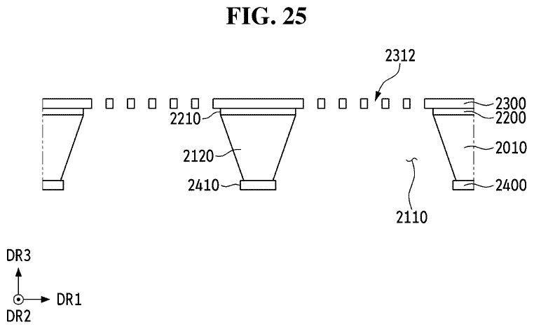

Referring to FIG. 25, after the cell openings 2110 are formed, the method may include removing the portions of the intermediate inorganic film 2200 exposed by the cell openings 2110 such that the pixel openings 2312 are connected to the cell openings 2110. For example, the method may include performing the second wet etching process in association with removing the portions of the intermediate inorganic film 2200 exposed by the cell openings 2110, such that the intermediate openings 2210 which penetrate the intermediate inorganic film 2200 may be formed. That is, the pixel openings 2312 may communicate with the cell openings 2110 through the intermediate openings 2210.

For example, the method may include performing the second wet etching process using an etchant containing hydrofluoric acid (HF), hydrogen peroxide (H₂O₂), acetic acid (CH₃COOH), and water (H₂O). As another example, the method may include performing the second wet etching process using an etchant containing ammonium hydroxide (NH₄OH), hydrogen peroxide (H₂O₂), and water (H₂O). In this case, a standard cleaning solution (SC-1) with a mixing ratio of ammonium hydroxide (NH₄OH), hydrogen peroxide (H₂O₂), and water (H₂O) of 1:5:1 or an etchant with a mixing ratio of ammonium hydroxide (NH₄OH), hydrogen peroxide (H₂O₂), and water (H₂O) of 1:5:20 may be used, and the etchant may further contain peroxyacetic acid (CH₃COOH), acetic acid (CH₃COOH), hydrofluoric acid (HF), and/or a surfactant. In some aspects, the second wet etching process may be performed at a temperature ranging from about 40° C. to about 80° C.

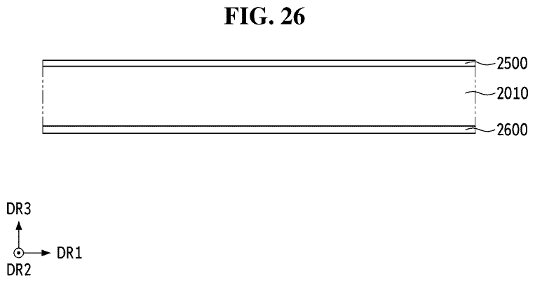

FIGS. 26 to 33 are schematic cross-sectional views illustrating a method of manufacturing a deposition mask according to still another embodiment of the present disclosure.

Referring to FIG. 26, the method may include forming the buffer inorganic film 2500 on the mask substrate 2010. For example, a single crystal silicon substrate may be used as the mask substrate 2010, and the buffer inorganic film 2500 may be formed to have a thickness ranging from about 0.5 μm to about 2 μm through a thermal oxidation process. That is, the buffer inorganic film 2500 may be formed of silicon oxide. In this case, the buffer inorganic film 2500 may be formed on the front surface of the mask substrate 2010, and the first rear inorganic film 2600 may be formed on the rear surface of the mask substrate 2010. By way of example, the first rear inorganic film 2600 may contain silicon oxide, and may be formed simultaneously with the buffer inorganic film 2500 through a thermal oxidation process.

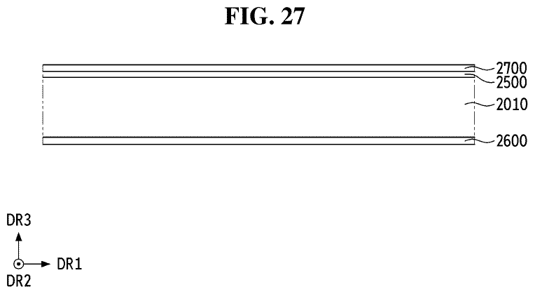

Referring to FIG. 27, the method may include forming the intermediate inorganic film 2700 on the buffer inorganic film 2500. The intermediate inorganic film 2700 may be formed of a material containing germanium (Ge), and may be formed to have a thickness ranging from about 50 nm to about 1 μm, e.g., about 0.5 μm, through an electron beam evaporation process, an LPCVD process, a PECVD process, or the like. For example, the intermediate inorganic film 2700 may be formed of amorphous germanium (Ge), polycrystalline germanium (Ge), or silicon germanium (SiGe). For example, the intermediate inorganic film 2700 may be formed through an LPCVD process using a germanium source gas such as, for example, GeH₄, GeF₄, Ge₂H₆, or the like. As another example, when the intermediate inorganic film 2700 contains silicon germanium (SiGe), a germanium source gas such as, for example, GeH₄, GeF₄, Ge₂H₆, or the like and a silicon source gas such as, for example, SiH₄, Si₂H₆, SiH₂Cl₂, or the like may be used.

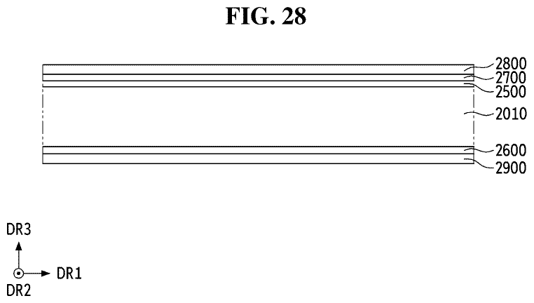

Referring to FIG. 28, the method may include forming the membrane 2800 on the intermediate inorganic film 2700. The membrane 2800 may be formed of silicon nitride (SiNx), and may be formed to have a thickness ranging from about 0.5 μm to about 3 μm through a TCVD process. For example, the membrane 2800 may be formed by a reaction between a silicon source gas such as, for example, SiH₄, Si₂H₆, SiH₂Cl₂, or the like and a nitrogen source gas such as, for example, ammonia (NH₃). In some embodiments, the second rear inorganic film 2900 may be formed on the first rear inorganic film 2600. For example, the second rear inorganic film 2900 may be formed simultaneously with the membrane 2800 by a TCVD process, and may be formed of the same material as the membrane 2800.

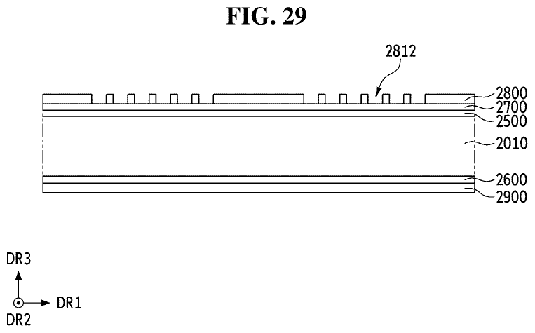

Referring to FIG. 29, the method may include patterning the membrane 2800 to form the plurality of pixel openings 2812 that partially expose the intermediate inorganic film 2700. For example, after forming on the membrane 2800 a first photoresist pattern (not illustrated) exposing the portions where the pixel openings 2812 are to be formed, the method may include performing an anisotropic etching process using the first photoresist pattern as an etching mask to form the pixel openings 2812 that expose the intermediate inorganic film 2700. For example, the pixel openings 2812 may be formed by an RIE process using a reaction gas such as, for example, CHF₃, CH₃F, CH₂F₂, CHF₆, CF₄, C₂F₆, C₃F₆, or the like and a sputtering gas such as, for example, Ar, O₂/Ar, or the like. In this case, the intermediate inorganic film 2700 may function as an etch stop film in the RIE process. The first photoresist pattern may be removed through a stripping and/or ashing process after the pixel openings 2812 are formed.

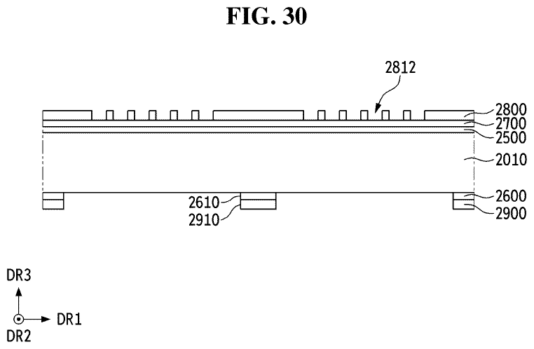

Referring to FIG. 30, the method may include patterning the first rear inorganic film 2600 and the second rear inorganic film 2900 to form the first rear openings 2610 and the second rear openings 2910, respectively. For example, after forming on the second rear inorganic film 2900 a second photoresist pattern (not illustrated) exposing the portions where the second rear openings 2910 are to be formed, the method may include performing an anisotropic etching process, such as, for example, an RIE process, using the second photoresist pattern as an etching mask. The method may include performing the anisotropic etching process until rear portions of the mask substrate 2010 are exposed. In this case, the first rear openings 2610 and the second rear openings 2910 may overlap the plurality of pixel openings 2812 in the third direction DR3. That is, the first rear openings 2610 and the second rear openings 2910 may expose the rear portions of the mask substrate 2010 where the cell openings 2110 are to be formed. The second photoresist pattern may be removed through a stripping and/or ashing process after the first rear openings 2610 and the second rear openings 2910 are formed.

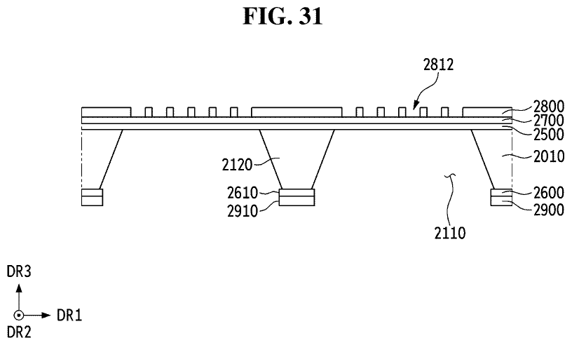

Referring to FIG. 31, the method may include patterning the mask substrate 2010 to form the cell openings 2110 that partially expose the buffer inorganic film 2500. For example, the method may include performing a first wet etching process using the first rear inorganic film 2600 and the second rear inorganic film 2900 as an etching mask. The mask substrate 2010 may be partially removed by the first wet etching process, and, as a result, the cell openings 2110 partially exposing the buffer inorganic film 2500 may be formed. That is, the rib region 2120 defining the cell openings 2110 may be formed by the first wet etching process.

In the first wet etching process, a KOH solution may be used as an etchant, and isopropyl alcohol (IPA) may be added to the etchant as a surfactant. The method may include performing the first wet etching process until the buffer inorganic film 2500 is exposed. In this case, the buffer inorganic film 2500 and the intermediate inorganic film 2700 may be used as an etch stop film in the first wet etching process, and, accordingly, the cell openings 2110 may be formed from the rear surface of the mask substrate 2010 toward the front surface of the mask substrate 2010. In this case, the intermediate inorganic film 2700 may prevent a KOH solution from being provided onto the front surface of the mask substrate 2010 through the pixel openings 2812 of the membrane 2800, thereby preventing damage to the membrane 2800 during the first wet etching process.

In the first wet etching process, the etching rate may be controlled by the temperature of the KOH solution. For example, the method may include controlling the etching rate in the first wet etching process by controlling the temperature of the KOH solution. In an example, the first wet etching process may be performed at a temperature ranging from about 40° C. to about 100° C. According to the present embodiment, the amount of time for performing the first wet etching process (i.e., the duration of the first wet etching process) may be reduced to about 6 hours or less, e.g., about 3 hours to about 4 hours, by appropriately controlling the concentration of KOH and the temperature of the KOH solution.

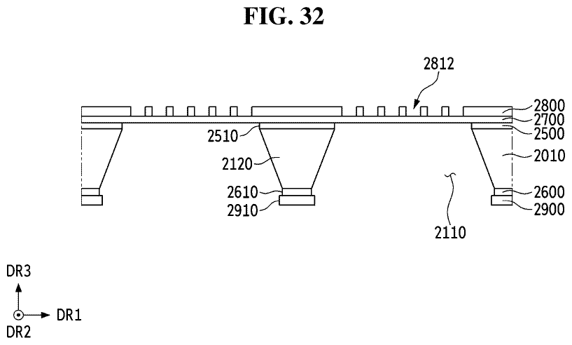

Referring to FIG. 32, after forming the cell openings 2110, the portions of the buffer inorganic film 2500 exposed by the cell openings 2110 may be removed. By way of example, the portions of the buffer inorganic film 2500 may be removed by the third wet etching process using an etchant such as, for example, BOE or diluted hydrofluoric acid (HF). The third wet etching process may be performed until the intermediate inorganic film 2700 is exposed, and the front openings 2510 penetrating the buffer inorganic film 2500 may be formed by the third etching process.

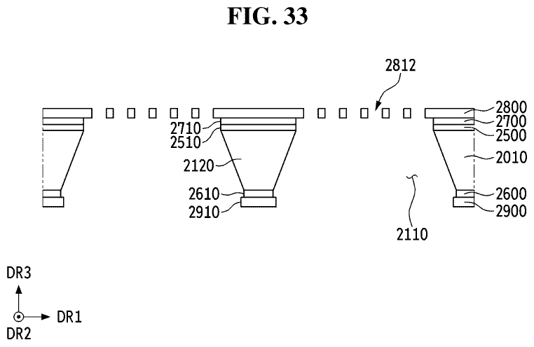

Referring to FIG. 33, the portions of the intermediate inorganic film 2700 exposed by the front openings 2510 may be removed such that the pixel openings 2812 are connected to the cell openings 2110. For example, the portions of the intermediate inorganic film 2700 exposed by the front openings 2510 may be removed by the second wet etching process, such that the intermediate openings 2710 penetrating the intermediate inorganic film 2700 may be formed. That is, the pixel openings 2812 may communicate with the cell openings 2110 through the intermediate openings 2710 and the front openings 2510. For example, the second wet etching process may be performed using an etchant containing hydrofluoric acid (HF), hydrogen peroxide (H₂O₂), acetic acid (CH₃COOH), and water (H₂O). As another example, the second wet etching process may be performed using an etchant containing ammonium hydroxide (NH₄OH), hydrogen peroxide (H₂O₂), and water (H₂O).

The invention should not be construed as being limited to the embodiments set forth herein. Rather, the example embodiments are provided such that this disclosure will be thorough and complete and will fully convey the concept of the invention to those skilled in the art.

While the invention has been particularly illustrated and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask frame having a cell opening;
an intermediate inorganic film disposed on the mask frame; and
a membrane disposed on the intermediate inorganic film and having a plurality of pixel openings which communicate with the cell opening,
wherein the intermediate inorganic film is formed of a material comprising germanium.

2. The deposition mask of claim 1, wherein the intermediate inorganic film is formed of at least one selected from the group consisting of amorphous germanium, single crystal germanium, polycrystalline germanium, and silicon germanium.

3. The deposition mask of claim 1, wherein:
the mask frame is formed of single crystal silicon, and
the intermediate inorganic film is formed of boron-doped germanium or boron-doped silicon germanium.

4. The deposition mask of claim 1, wherein the intermediate inorganic film has a thickness ranging from 50 nm to 1 μm.

5. The deposition mask of claim 1, wherein the membrane is formed of silicon nitride and has a thickness ranging from 0.5 μm to 3 μm.

6. The deposition mask of claim 1, further comprising a buffer inorganic film disposed between the mask frame and the intermediate inorganic film.

7. The deposition mask of claim 6, wherein the buffer inorganic film is formed of silicon oxide and has a thickness ranging from 0.5 μm to 2 μm.

8. A method of manufacturing a deposition mask, comprising:
forming an intermediate inorganic film on a mask substrate;
forming, on the intermediate inorganic film, a membrane having a plurality of pixel openings;
patterning the mask substrate, wherein patterning the mask substrate forms a cell opening partially exposing the intermediate inorganic film; and
removing a portion of the intermediate inorganic film exposed by the cell opening such that the cell opening communicates with the plurality of pixel openings,
wherein the intermediate inorganic film is formed of a material comprising germanium.

9. The method of claim 8, wherein the intermediate inorganic film is formed of at least one selected from the group consisting of amorphous germanium, single crystal germanium, polycrystalline germanium, and silicon germanium.

10. The method of claim 8, wherein:
the mask substrate is formed of single crystal silicon, and
the intermediate inorganic film is formed of boron-doped germanium or boron-doped silicon germanium.

11. The method of claim 8, wherein the intermediate inorganic film is formed such that the intermediate inorganic film has a thickness ranging from 50 nm to 1 μm.

12. The method of claim 8, wherein the membrane is formed of silicon nitride and is formed such that the membrane has a thickness ranging from 0.5 μm to 3 μm.

13. The method of claim 8, wherein patterning the mask substrate comprises forming the cell opening by performing a wet etching process using an etchant comprising potassium hydroxide (KOH).

14. The method of claim 13, wherein the wet etching process is performed at a temperature of ranging from 40° C. to 100° C.

15. The method of claim 8, wherein removing the portion of the intermediate inorganic film exposed by the cell opening comprises performing a wet etching process using an etchant comprising hydrofluoric acid (HF), hydrogen peroxide (H₂O₂), acetic acid (CH₃COOH), and water (H₂O).

16. The method of claim 8, wherein removing the portion of the intermediate inorganic film exposed by the cell opening comprises performing by a wet etching process using an etchant comprising ammonium hydroxide (NH₄OH), hydrogen peroxide (H₂O₂), and water (H₂O).

17. The method of claim 8, further comprising forming a buffer inorganic film on the mask substrate,
wherein the buffer inorganic film is formed of silicon oxide and is formed such that the buffer inorganic film has a thickness ranging from 0.5 μm to 2 μm, and
the intermediate inorganic film is formed on the buffer inorganic film.

18. The method of claim 17, further comprising partially removing the buffer inorganic film such that the intermediate inorganic film is partially exposed by the cell opening.

19. The method of claim 8, further comprising forming, on a rear surface of the mask substrate, a rear inorganic film exposing a rear portion of the mask substrate,
wherein patterning the mask substrate comprises forming the cell opening by performing a wet etching process using the rear inorganic film as an etching mask.

20. An electronic device comprising a display panel,
wherein the display panel comprises:
a substrate; and
light emitting layers formed on the substrate using a deposition mask, and
the deposition mask comprises:
a mask frame having a cell opening;
an intermediate inorganic film disposed on the mask frame; and
a membrane disposed on the intermediate inorganic film and having a plurality of pixel openings which communicate with the cell opening,
wherein the intermediate inorganic film is formed of a material comprising germanium.
